(19) United States
(12) Patent Application Publication
(10) Pub. No.: US 2022/0384789 A1
(43) Pub. Date: Dec. 1, 2022

(54) SURFACE-STABILIZED LINIO2 AS HIGH CAPACITY CATHODE FOR LI ION BATTERIES

(71) Applicant: Board of Regents, The University of Texas System, Austin, TX (US)

(72) Inventors: Kyeongjae Cho, Austin, TX (US); Fantai Kong, Austin, TX (US)

(21) Appl. No.: 17/771,907

(22) PCT Filed: Oct. 31, 2020
(86) PCT No.: PCT/US2020/058440

§ 371 Date: Apr. 26, 2022

Related U.S. Application Data
(60) Provisional application No. 62/929,466, filed on Nov. 1, 2019.

(51) Int. Cl. H01M 4/36; H01M 4/58; H01M 4/525; H01M 4/48; H01M 4/04; C23C 16/44; C23C 16/40

(52) U.S. Cl. CPC H01M 4/366; H01M 4/582; H01M 4/525; H01M 4/483; H01M 4/0428; C23C 16/4417; C23C 16/405; C23C 16/407; C23C 16/403; H01M 2004/028

(57) ABSTRACT

Cathode composition including a core cathode body composed of nickel oxide crystallite particles and a surface cathode coating layer contacting and at least partially surrounding an outer surface of the core cathode body. The surface cathode coating layer includes one or more of a transition metal or post-transition metal oxide or fluoride and one or more of lanthanide row atoms having a concentration in a range from about 0.1 to 10 mol %, has a thickness in a range from about 0.5 to 30 nm, and has an amorphous, polycrystalline or composite amorphous/polycrystalline atomic structure. Method of manufacture including preparing a cathode composition includes forming a core cathode body composed of nickel oxide crystallite particles, and, forming by atomic layer deposition, a surface cathode coating layer contacting and at least partially surrounding an outer surface of the core cathode body.

### CROSS-REFERENCE TO RELATED APPLICATION

This application claims the benefit of U.S. Provisional Application Ser. No. 62/929,466, filed by Kyeongjae Cho, et al. on Nov. 1, 2019, entitled “SURFACE-STABILIZED LINIO₂ AS HIGH CAPACITY CATHODE FOR LI ION BATTERIES,” commonly assigned with this application and incorporated herein by reference in its entirety.

### TECHNICAL FIELD

This application is directed, in general, methods of surface stabilizing Lithium ion batteries and compositions having such surface stabilization

### BACKGROUND

Due to a high charge capacity of about 200 mAh/g or higher, LiNiO₂ is viewed as the next generation cathode materials for Li ion battery. However, capacity degradation and oxygen loss are the main obstacles for its ultimate commercialization.

### SUMMARY

The present disclosure provides in one embodiment, a cathode composition including a a core cathode body and a surface cathode coating layer. The core cathode body is composed of nickel oxide crystallite particles. The surface cathode coating layer contacts and at least partially surrounds an outer surface of the core cathode body. The surface cathode coating layer includes one or more of a transition metal or post-transition metal oxide or fluoride and one or more of lanthanide row atoms having a concentration in a range from about 0.1 to 10 mol %. The surface cathode coating layer has a thickness in a range from about 0.5 to 30 nm, and has an amorphous, polycrystalline or composite amorphous/polycrystalline atomic structure.

Another embodiment of the disclosure is a method of manufacture that includes preparing a cathode composition. Preparing the cathode composition includes forming a core cathode body, the core cathode body composed of nickel oxide crystallite particles. Preparing the cathode composition includes forming by atomic layer deposition (ALD), a surface cathode coating layer contacting and at least partially surrounding an outer surface of the core cathode body. The surface cathode coating layer includes one or more of a transition metal or post-transition metal oxide or fluoride, one or more of lanthanide row atoms having a concentration in a range from about 0.1 to 10 mol %, has a thickness in a range from about 0.5 to 30 nm, and has an amorphous, polycrystalline or composite amorphous/polycrystalline atomic structure. In some such embodiments of the composition, the surface cathode coating layer can have the composite amorphous/polycrystalline atomic structure with greater than 20 to less than 80% crystalline and balance amorphous atomic structures. In some such embodiments of the composition, the surface cathode coating layer can have the polycrystalline atomic structure with 80% or greater crystalline structures.

### BRIEF DESCRIPTION

For a more complete understanding of the present disclosure, reference is now made to the following detailed description taken in conjunction with the accompanying FIGUREs.

Reference is now made to the following descriptions taken in conjunction with the accompanying drawings, in which:

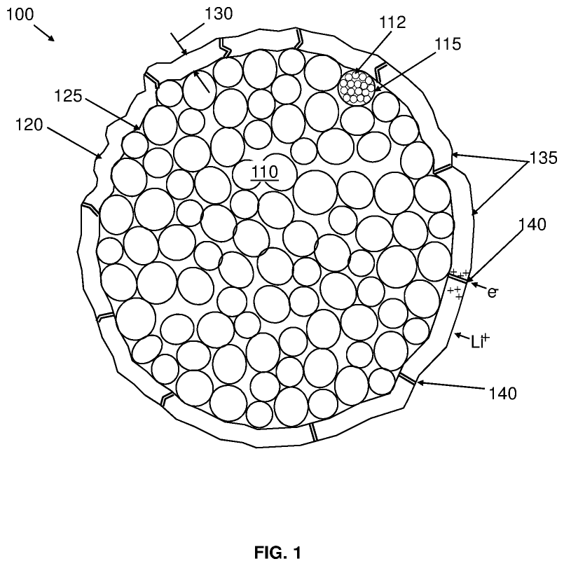

FIG. 1 schematic representation of a cross-sectional view of a cathode composition embodiment of the disclosure;

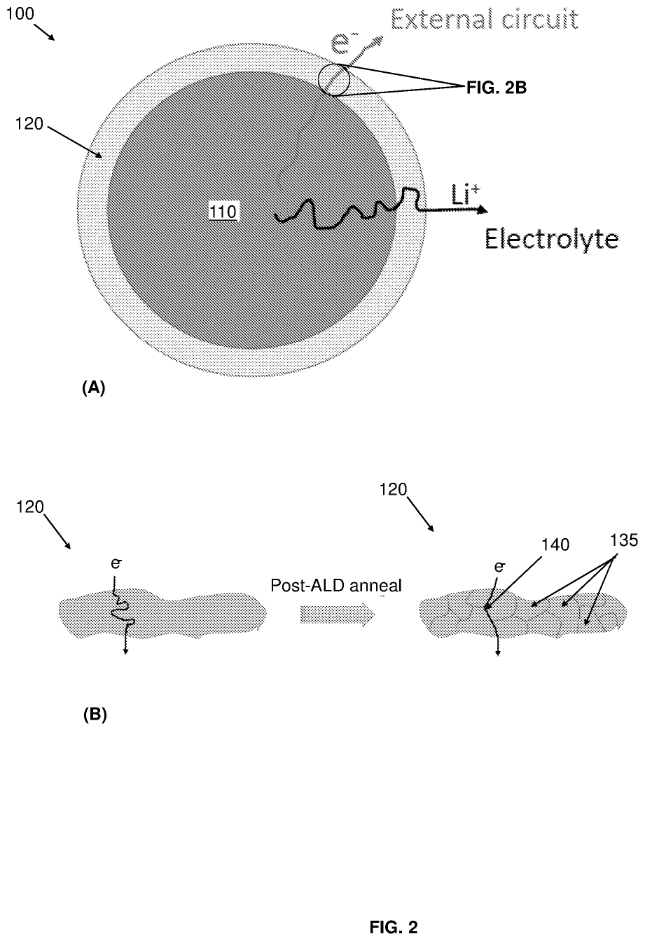

FIG. 2 (A) schematic representation of the cathode composition analogous to that depicted in FIG. 1, (B) detailed schematic representation view of a portion of a surface cathode coating layer of the cathode composition before and after a thermal anneal;

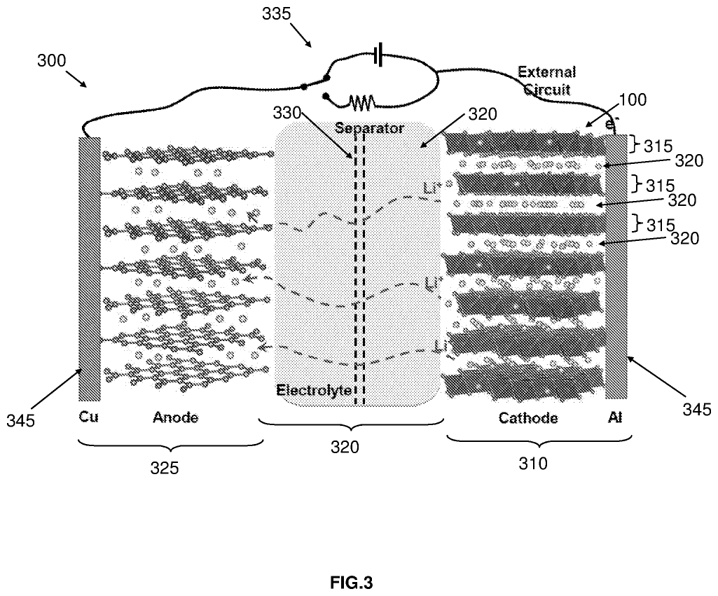

FIG. 3 schematic representation of a cross-section view of a battery assembly that includes the cathode composition, including any of the embodiments of the composition disclosed herein;

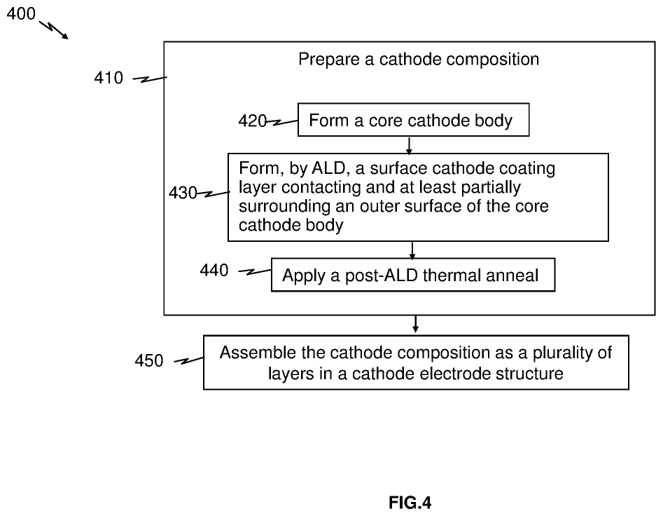

FIG. 4 flow diagram of example method of manufacture embodiments of the disclosure;

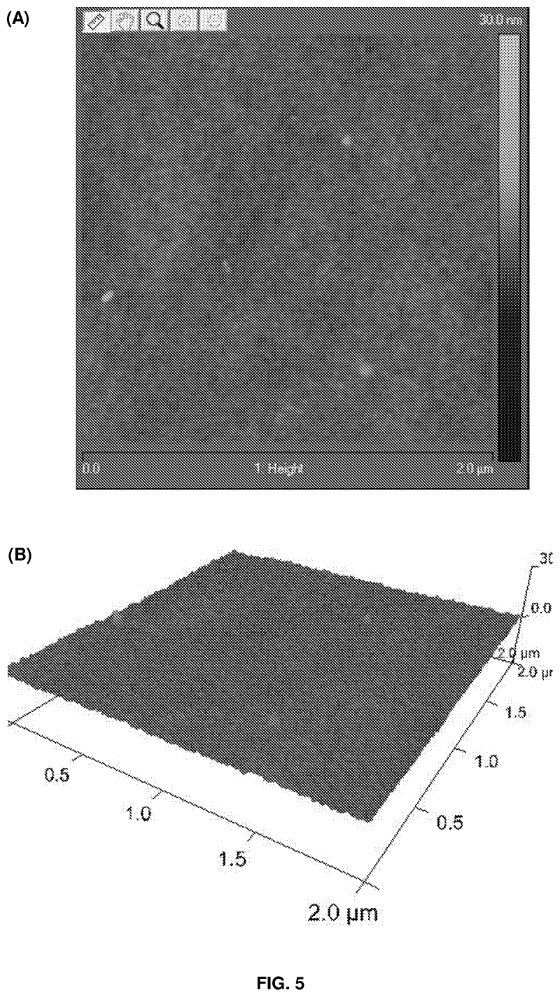

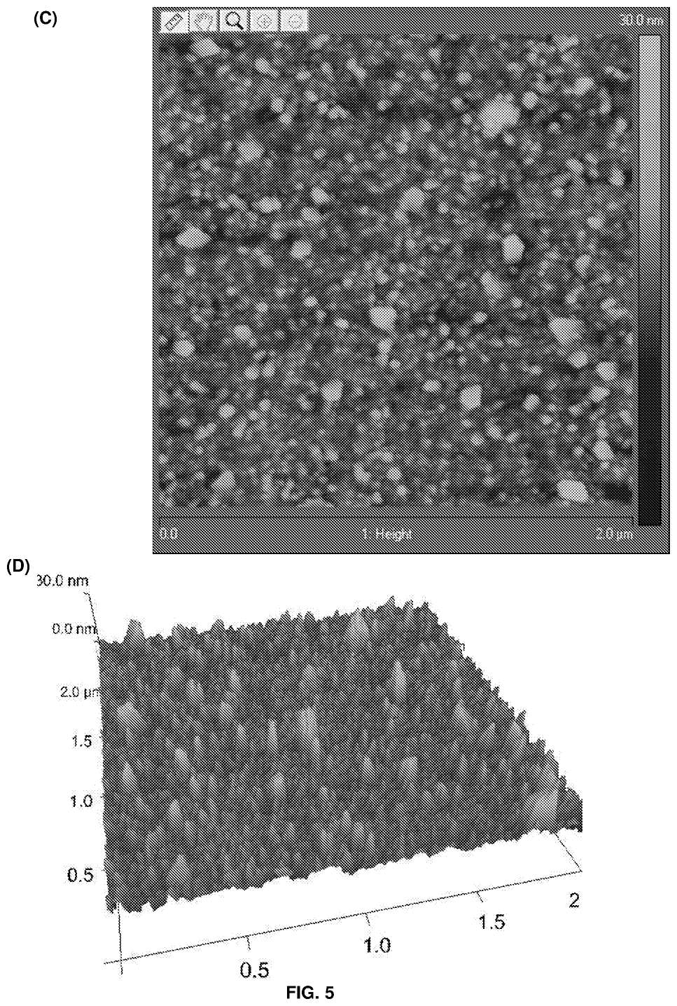

FIG. 5 (A) SEM surface image of an Al₂O₃ film deposited on a silicon wafer by ALD, (B) height profile of a portion of the Al₂O₃ film shown in FIG. 5(A), (C) SEM surface image of an Al₂O₃3 film deposited on a silicon wafer by ALD and further subjected to a post ALD thermal anneal for 6 hr at 600° C. in air, (D) height profile of a portion of the Al₂O₃ film shown in FIG. 5(C);

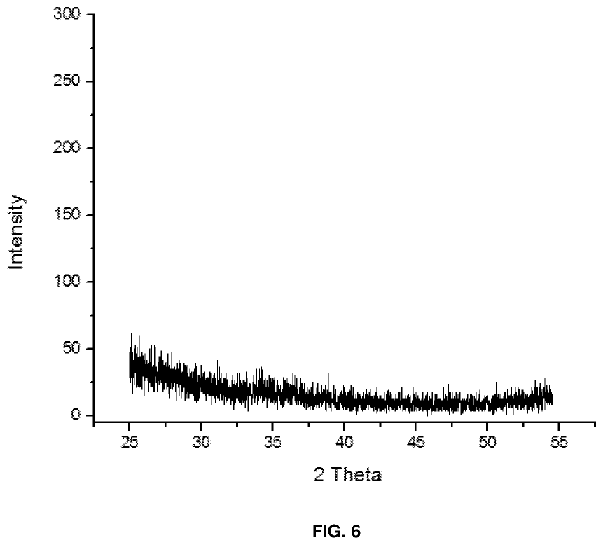

FIG. 6 XRD profile of an Al₂O₃ film formed and thermally annealed in the same manner as described in the context of FIG. 5C;

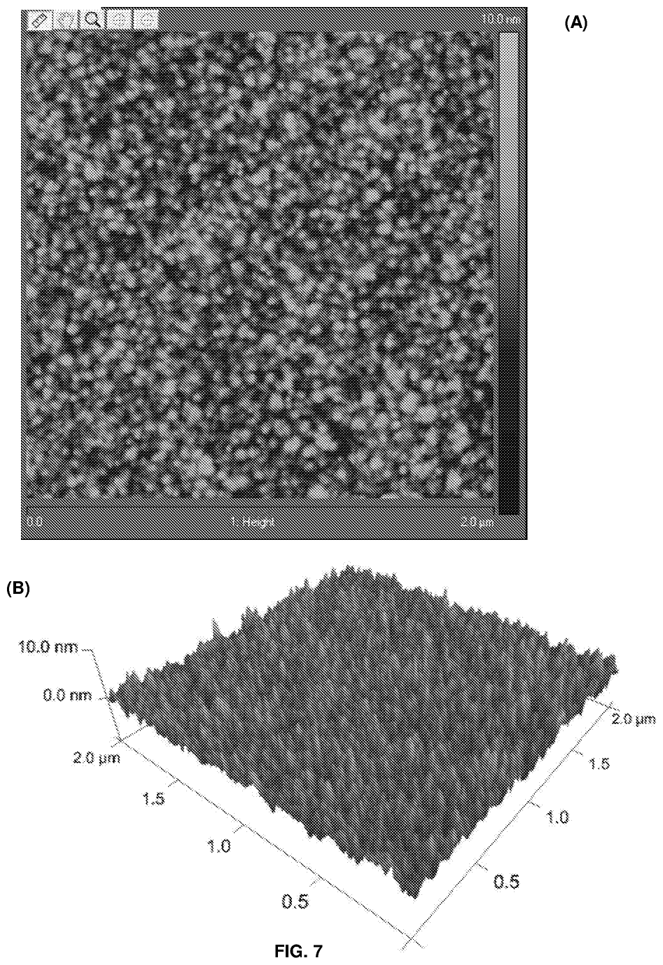

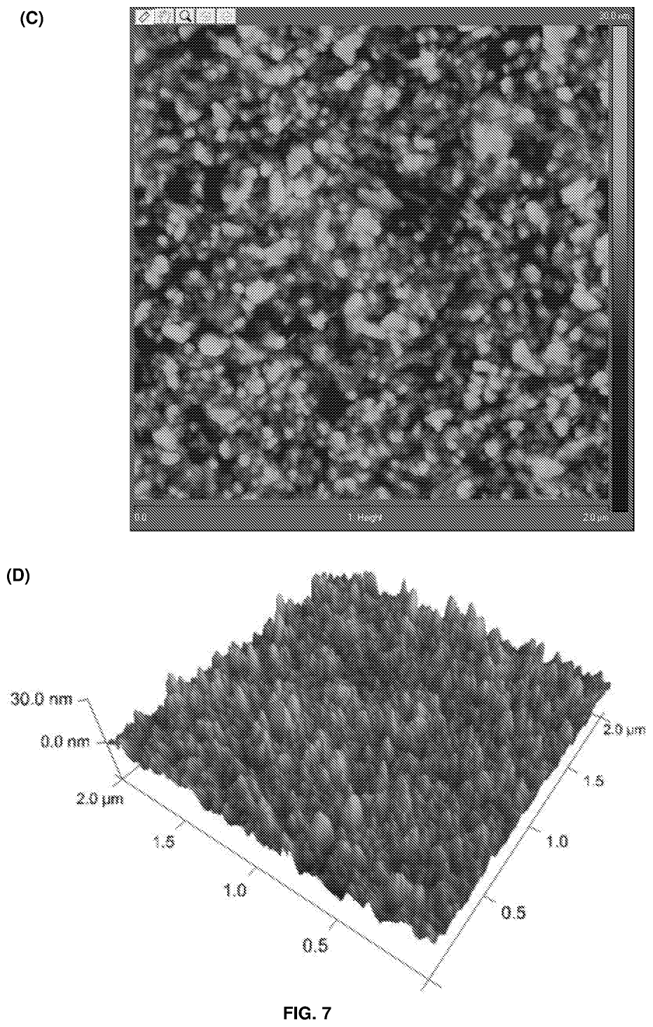

FIG. 7 (A) SEM surface image of an TiO₂ film deposited on a silicon wafer by ALD, (B) height profile of a portion of the TiO₂ film shown in FIG. 7(A), (C) SEM surface image of an TiO₂ film deposited on a silicon wafer by ALD and further subjected to a post ALD thermal anneal for 2 hr at 600° C. in air, (D) height profile of a portion of the TiO₂ film shown in FIG. 7(C);

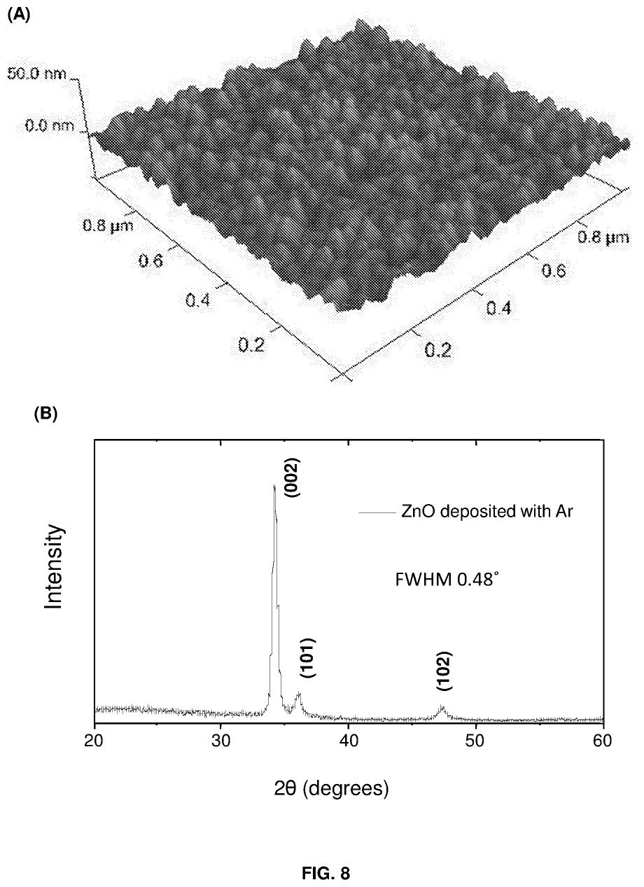

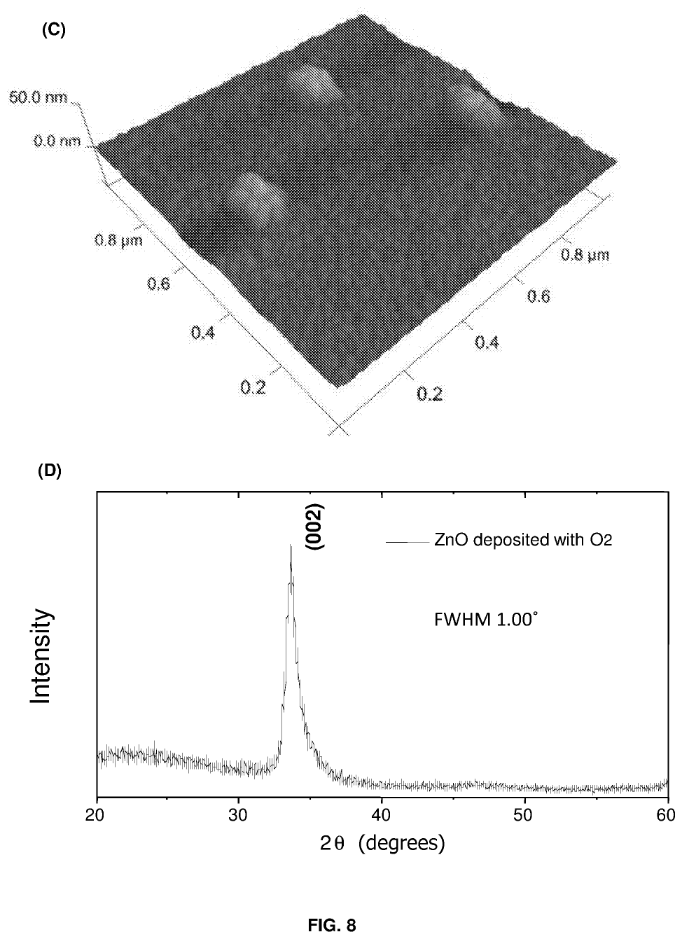

FIG. 8 (A) height profile from a SEM surface image of a portion of a ZnO film deposited on a silicon wafer by ALD with Ar, (B) XRD profile of a ZnO film formed in the same manner as described in the context of FIG. 8A, (C) height profile from a SEM surface image of a portion of a ZnO film deposited on a silicon wafer by ALD with O₂, (D) XRD profile of a ZnO film formed in the same manner as described in the context of FIG. 8C;

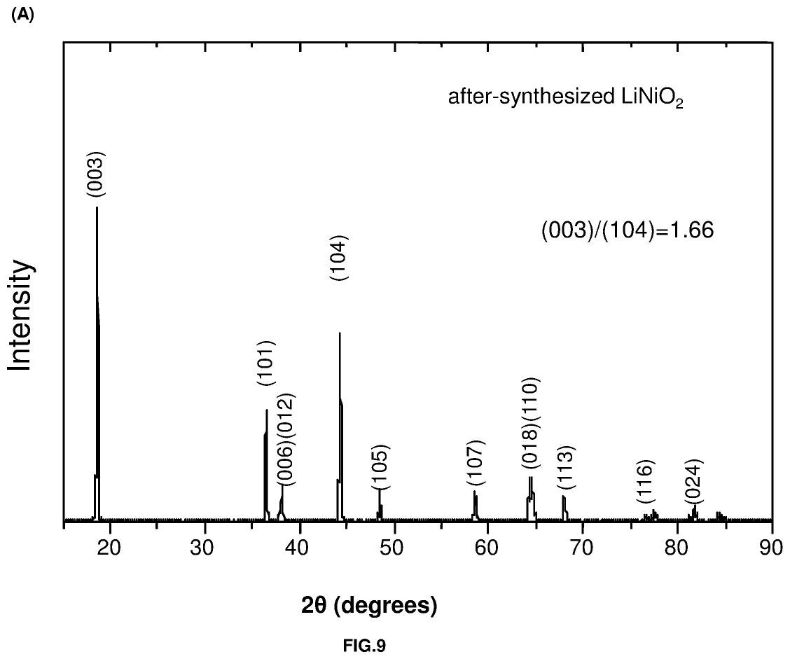

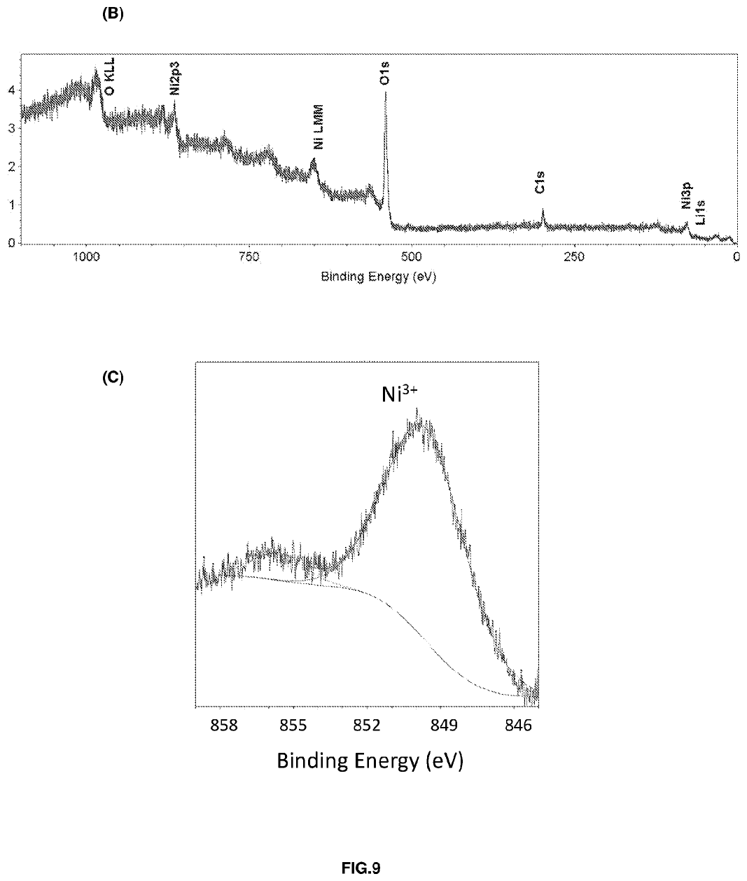

FIG. 9 (A) XRD profile of LiNiO₂ powder formed as described in the Experimental Results, (B) XPS profile of LiNiO₂ powder, (C) detailed view of a portion of XPS profile shown in FIG. 9(B);

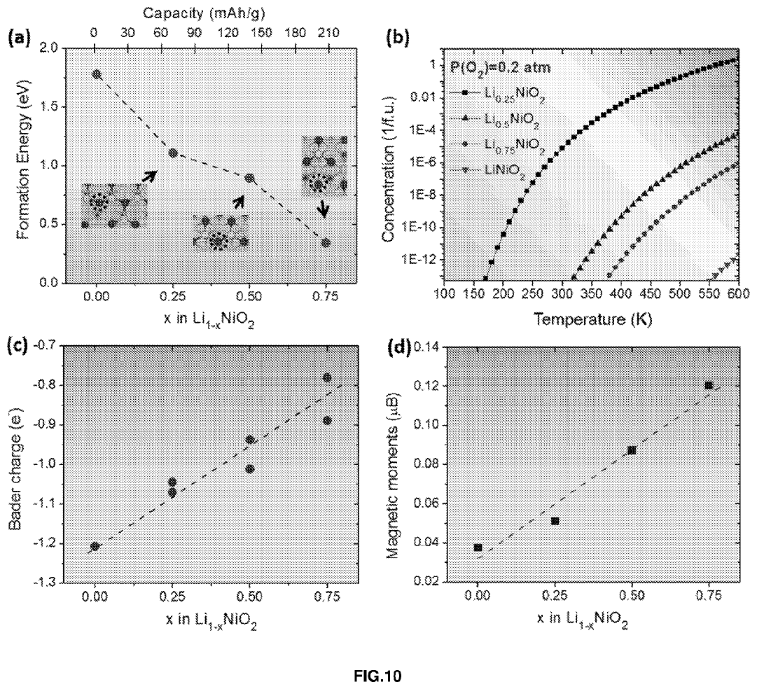

FIG. 10 (a) Oxygen vacancy formation energy during delithiation of LiNiO₂, (b) concentration of oxygen vacancy at thermal equilibrium at different delithiation states as a function of temperature, (c) Bader charges, and (d) magnetic moments of oxygen ions during delithiation of LiNiO₂;

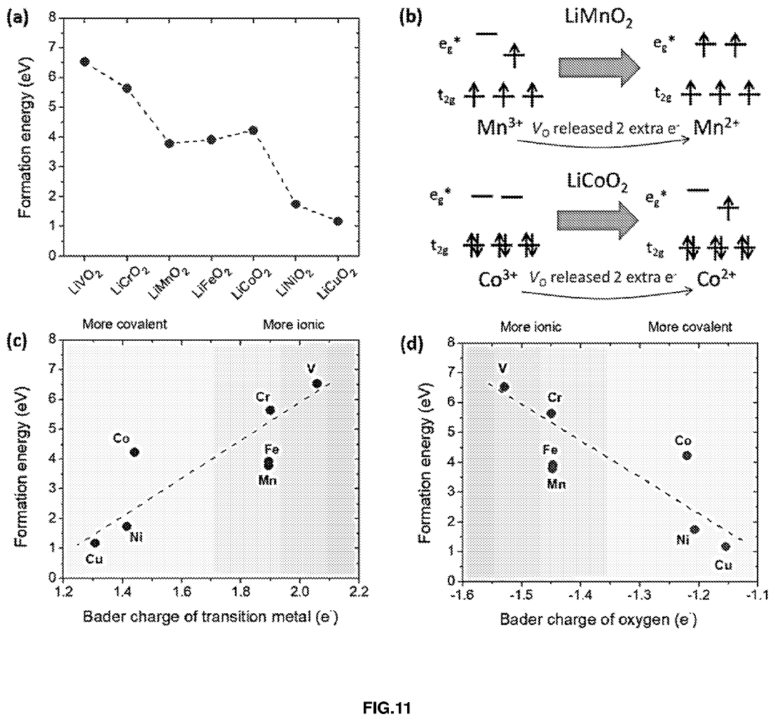

FIG. 11 (a) Oxygen vacancy formation energy of layered LiMeO₂ oxides, (b) illustration of Jahn-Teller distortion changes upon oxygen vacancy formation in LiMnO₂ and LiCoO₂ (c) Bader charges of transition metal, (d) and oxygen in LiMeO₂, (e) bonding orbital energy levels of isolated atom in vacuum, and (f) illustration of Molecular Orbital Theory analysis on Me-O bonding formation;

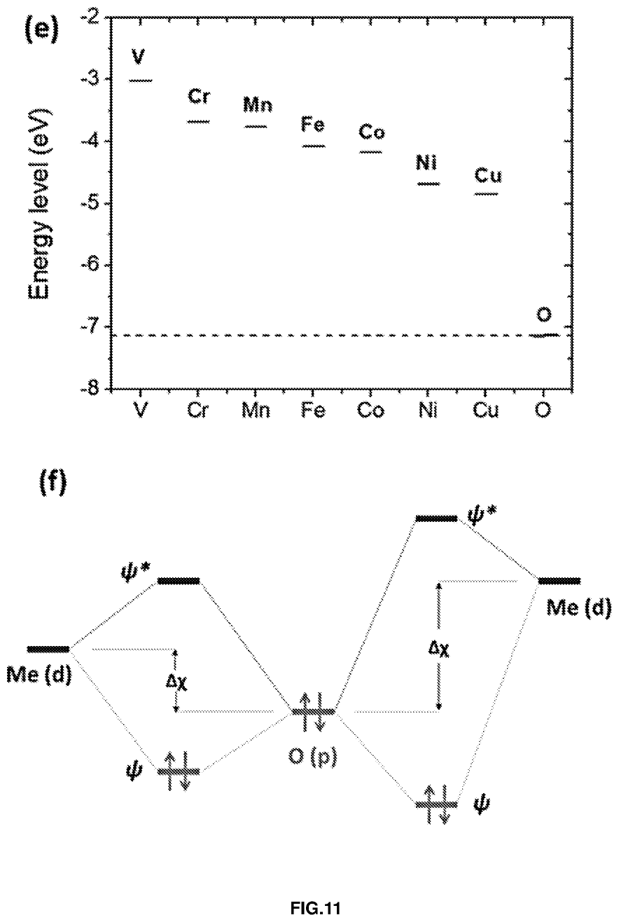

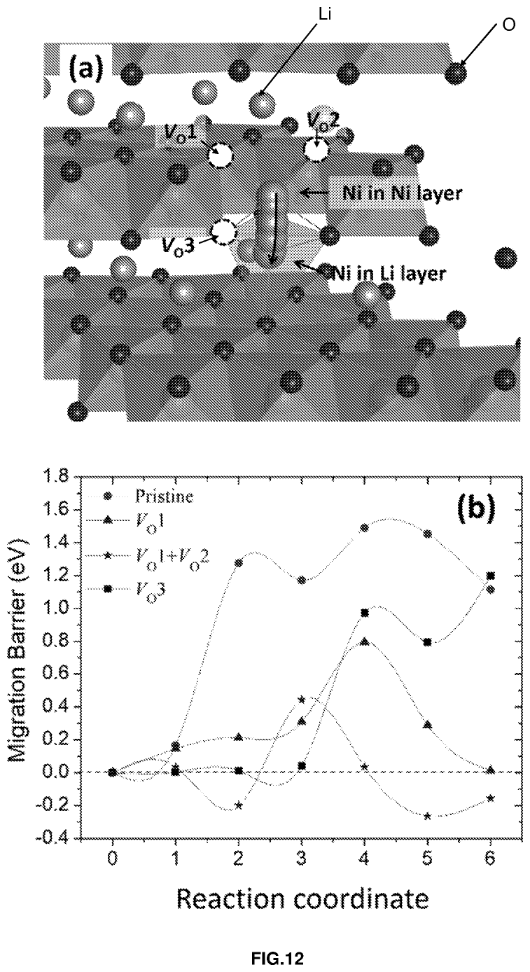

FIG. 12 (a) Configuration for Ni migration in Li_{0.5}NiO₂, V_{O}1, V_{O}2, and V_{O}3 represent oxygen vacancies neighboring with diffusive Ni ion, (b) The migration barriers for Ni ions to diffuse from transition metal layer to Li layer, under different situations (Pristine: no neighboring oxygen vacancy; V_{O}1: with neighboring vacancy V_{O}1; V_{O}1+V_{O}2: with neighboring vacancies V_{O}1 and V_{O}2; V_{O}3: with neighboring vacancy V_{O}3) and different sized and shaded spheres represent Li, Ni and O atoms, respectively as labeled;

FIG. 13 (a) Configuration of oxygen dimer formation in Li_{0.25}NiO₂ by diffusion of two O atoms from original positions to Li layer and (b) the corresponding migration barrier;

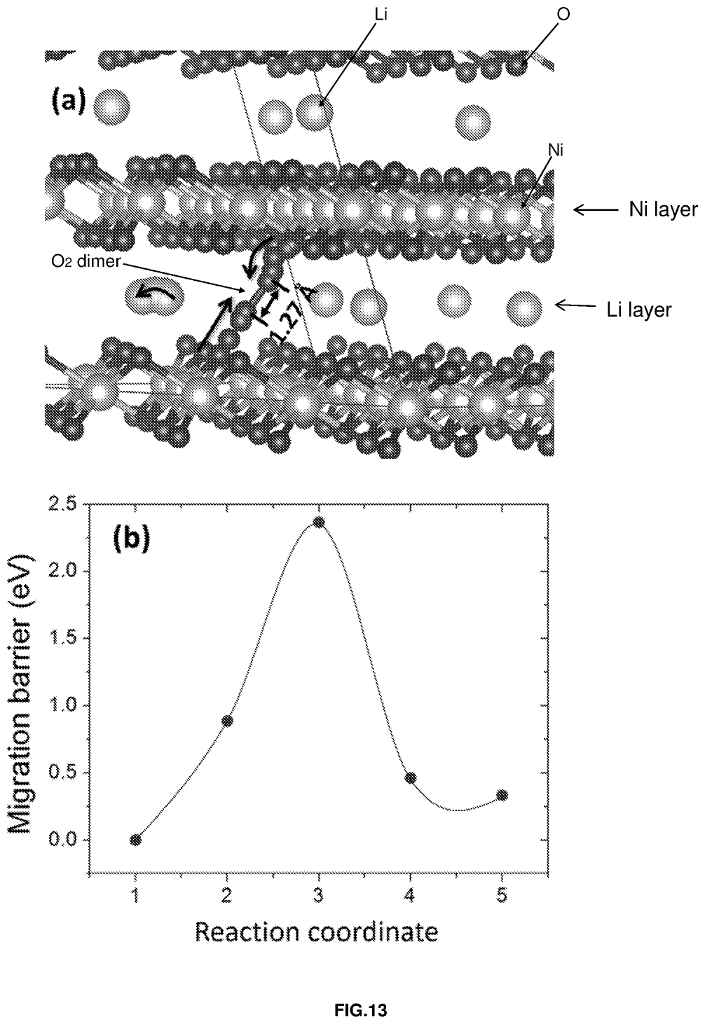

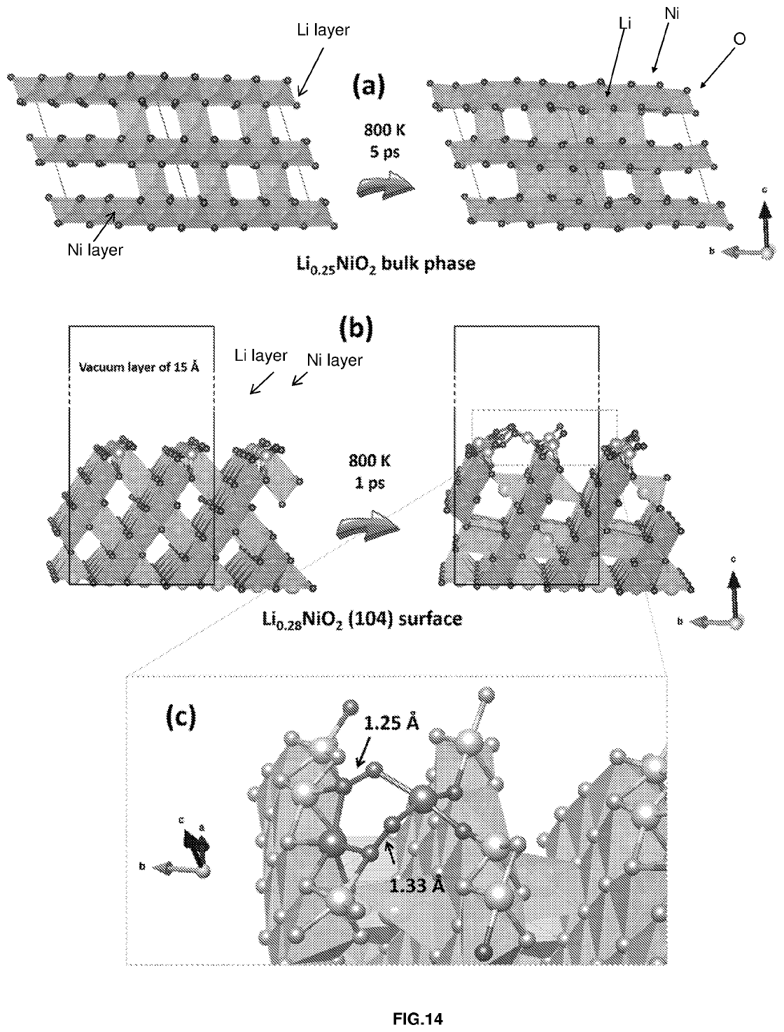

FIG. 14 Atomic structure changes of: (a) Li_{0.25}NiO₂ after 5 ps at 800 K, (b) Li_{0.26}NiO₂ (104) surface after 1 ps at 800 K from ab initio molecular dynamics (AIMD) simulations, (c) the zoom-in of distorted surface structures on (104) surface after 1 ps at 800° K;

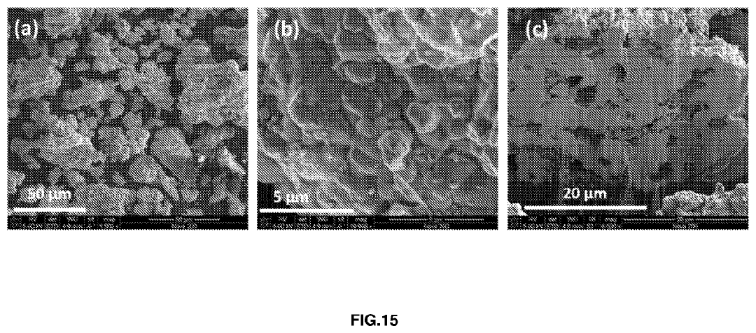

FIG. 15 (a) SEM, (b) zoom-in SEM, (c) cross section SEM, (d) XRD characterization of sol-gel synthesized LiNiO₂ powders, and (e) the first charging/discharging profile of LiNiO₂Li half cell at current rate of 0.1 C with cut-off voltage of 4.3 V;

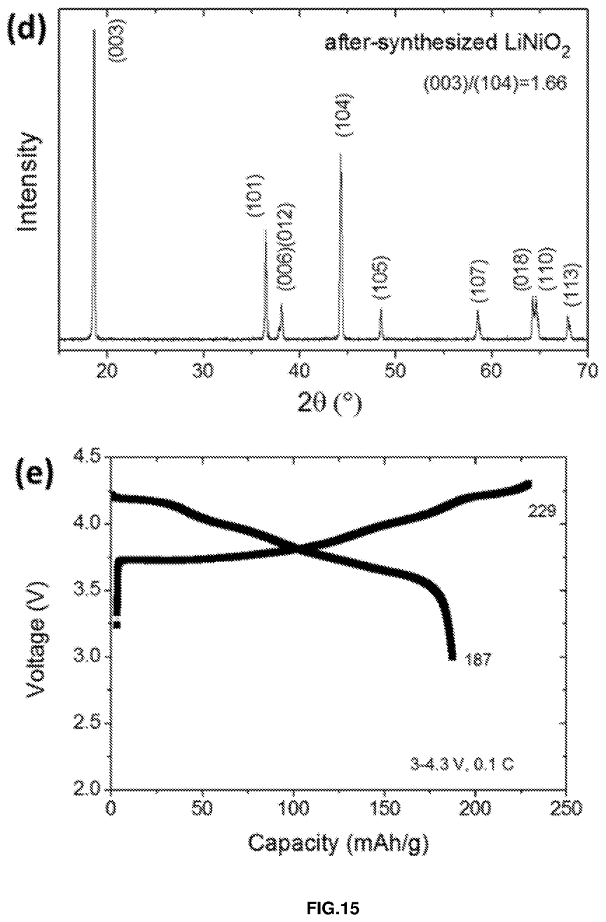

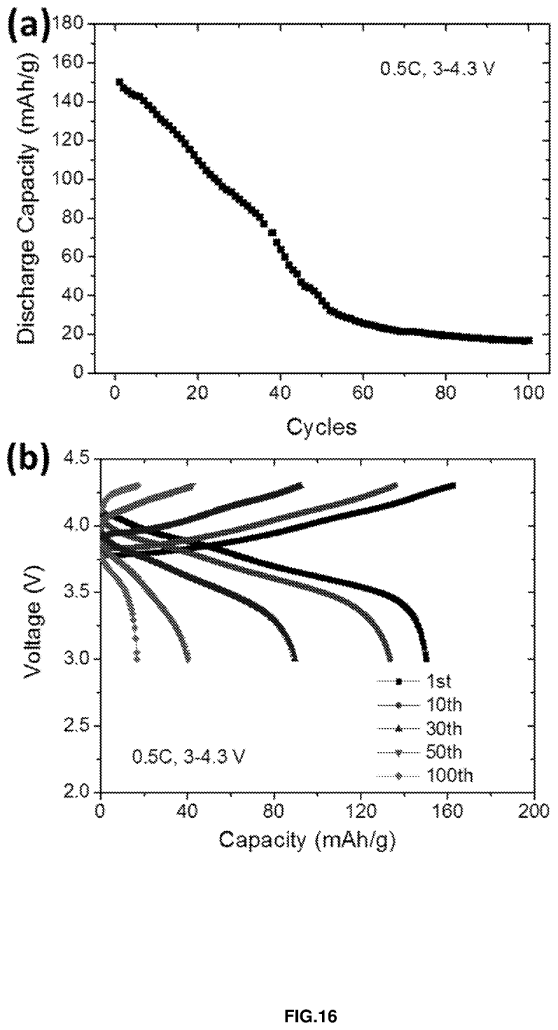

FIG. 16 (a) Discharge capacity of LiNiO₂Li half cell upon 100 charging/discharging cycles at 0.5 C with cut-off voltage of 4.3 V, (b) the corresponding voltage-capacity profiles, (c) the XRD profiles LiNiO₂ powders before (after-synthesized) and after 100^{th} cycling, and (d) the Ni and O relative atomic concentrations in bulk and surface phases before and after LiNiO₂ cycling. (EDS and XPS are used to define atomic concentration in bulk phase and surface region, respectively.);

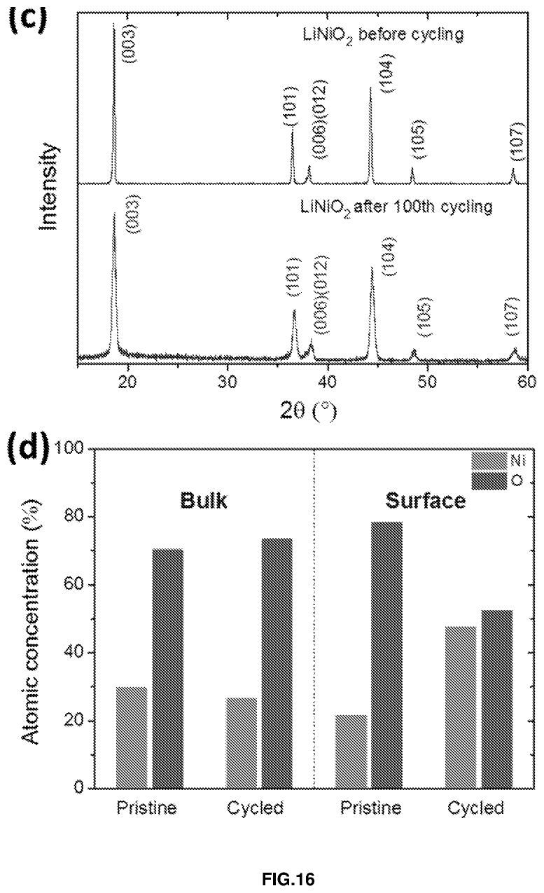

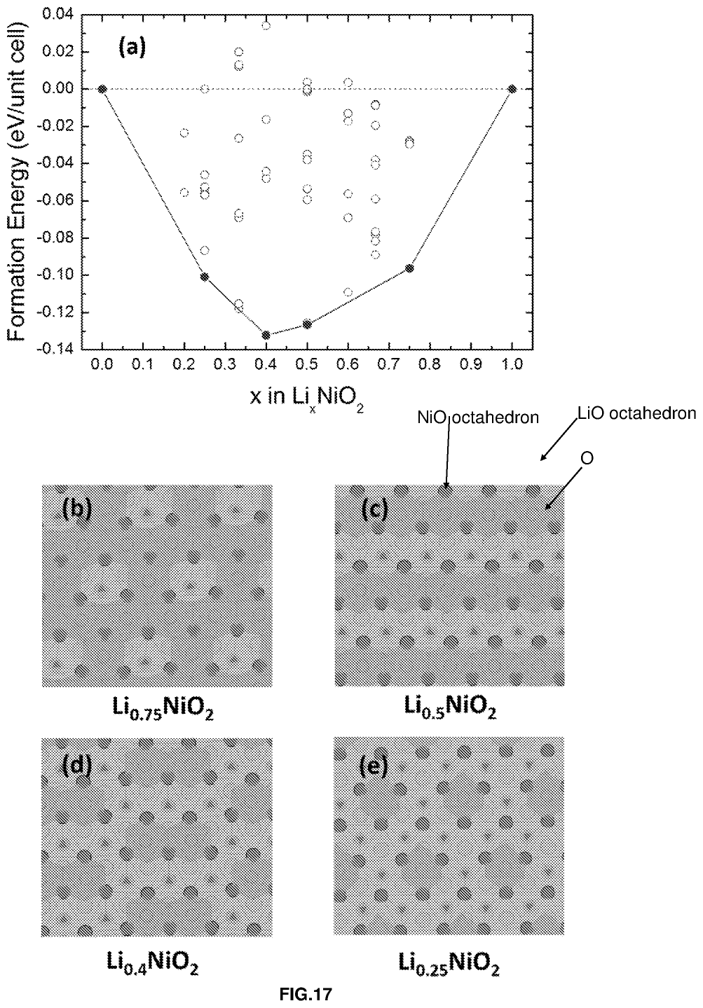

FIG. 17 (a) Formation energies calculated from the 62 different configurations during delithiation of LiNiO₂. (b) the configurations of intermediate stable LiₓNiO₂ with x=0.75, (c) x=0.5, (d) x=0.4 and (E) x=0.25;

FIG. 18 Concentration of oxygen vacancy at thermal equilibrium in deep-charged LiNiO₂ (Li_{0.25}NiO₂) under different oxygen partial pressures as a function of temperature;

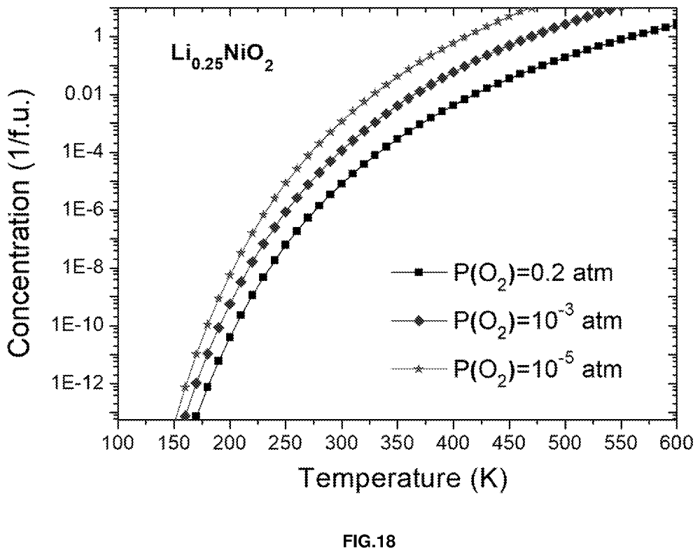

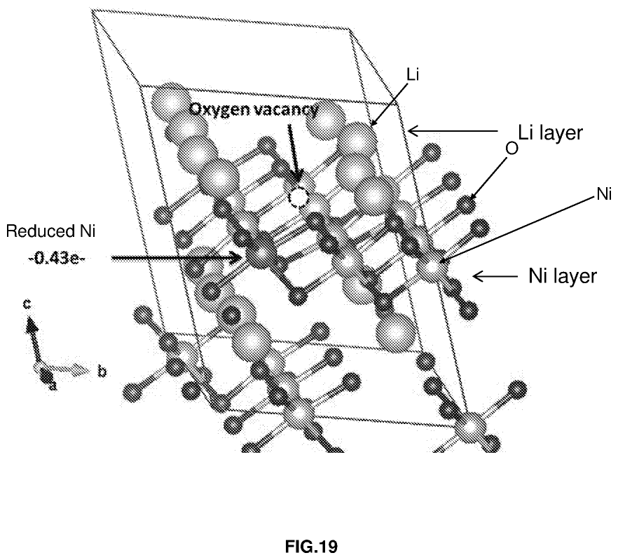

FIG. 19 Illustration of Ni reduction due to oxygen vacancy formation;

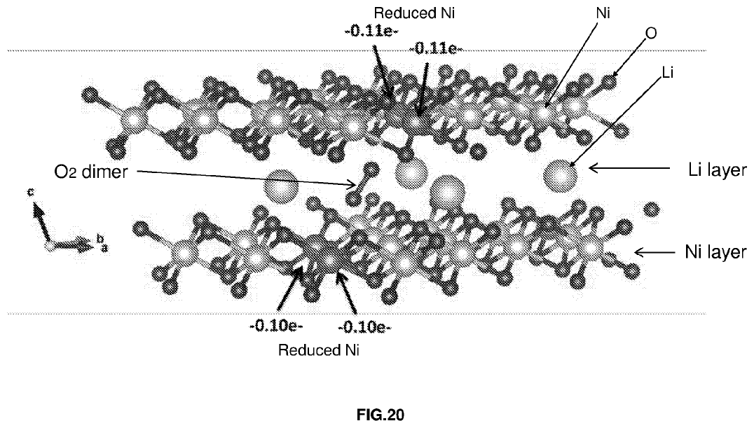

FIG. 20 Illustration of Ni reduction due to oxygen dimer formation;

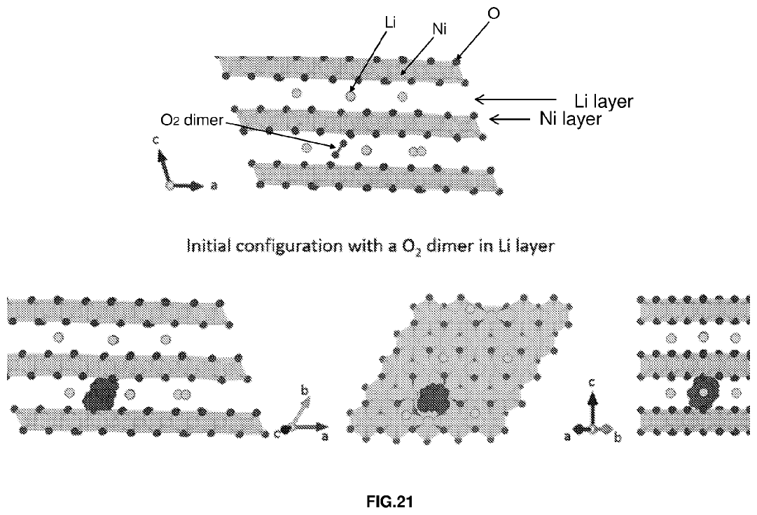

FIG. 21 Trajectories of O₂ dimer in Li layer at 800 K for 10 ps, obtained from ab initio molecular dynamics (AIMD);

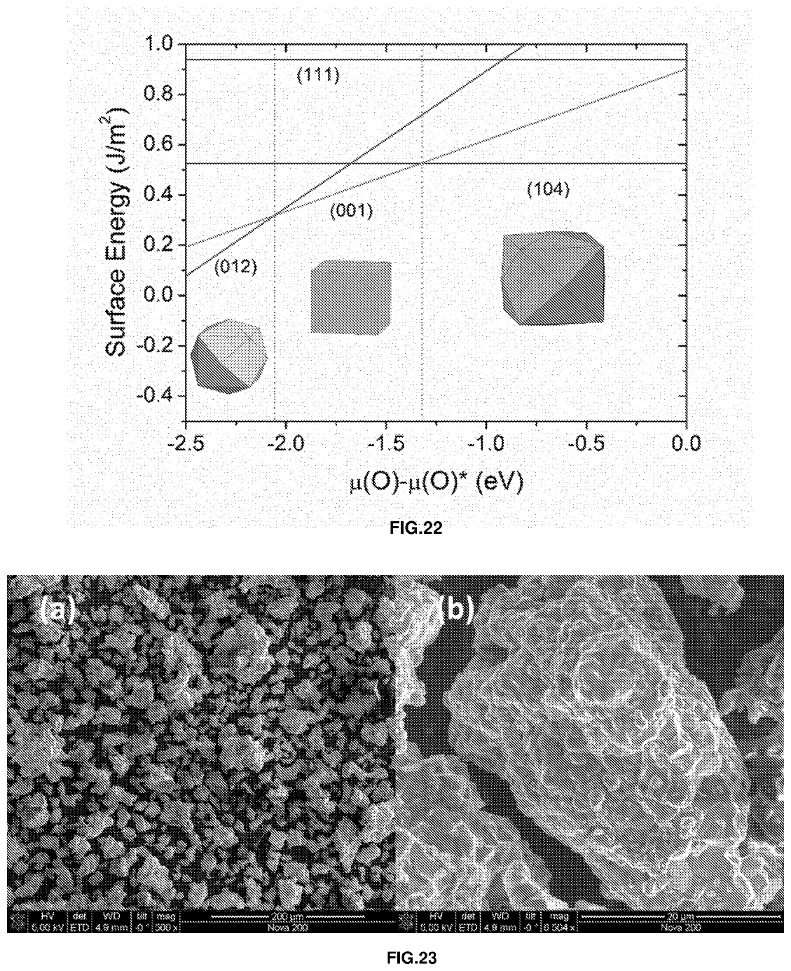

FIG. 22 Surface energy of LiNiO₂ as a function of oxygen chemical potential. The sandwich model with two symmetric surfaces on both sides is used for surface energy calculation, and the vacuum layer is set to be 15 Å to avoid layer-layer interaction, where surface energy is defined as

$$= \frac{{E}_{tot} - {E}_{bulk} + {\sum }_{i} {n}_{i} {μ}_{i}}{2 A} ,$$

in which Eₜₒₜ and E_{bulk} are the total energies of surface and bulk phases, respectively, nonstoichiometric surfaces were calculated by considering the chemical potential pi of the elements in excess or shortage of nᵢ, and, as illustrated, an O-rich environment would induce the predominate (104) surfaces;

FIG. 23 SEM profile after-synthesized LiNiO₂ powders at different resolutions corresponding to: (a) 500 and (b) 6504 times magnifications;

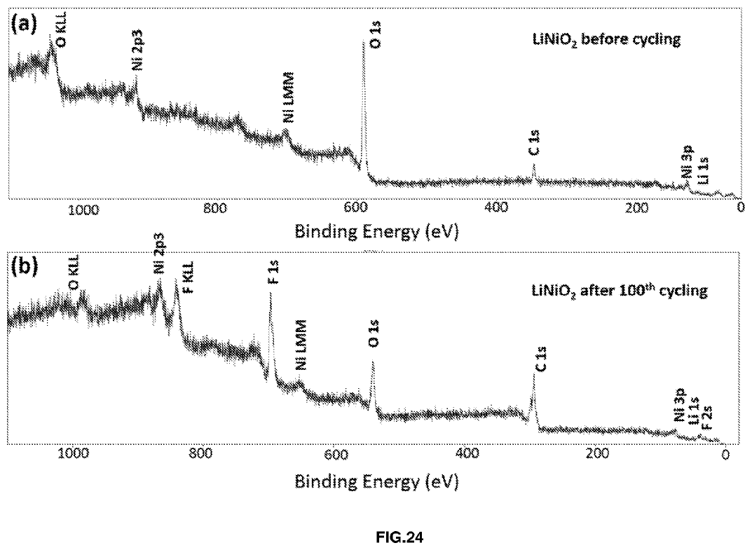

FIG. 24 XPS survey of elements in LiNiO₂ powders (a) before and (b) after cycling, and where the fluorine peak originates from LiPF₆ salt in electrolyte and PVDF polymer binder;

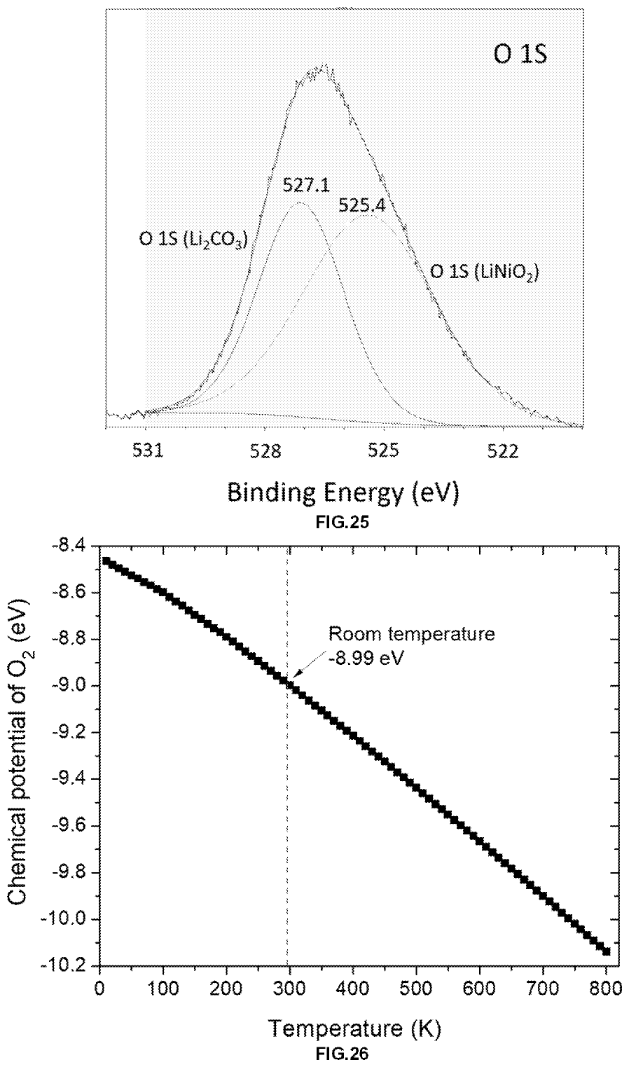

FIG. 25 XPS Oxygen (O) is peak of pristine LiNiO₂, where fitting is finished through CasaXPS software and the peak has been allied to Carbon is at 284.8 eV;

FIG. 26 Chemical potential of O₂ as a function of temperature;

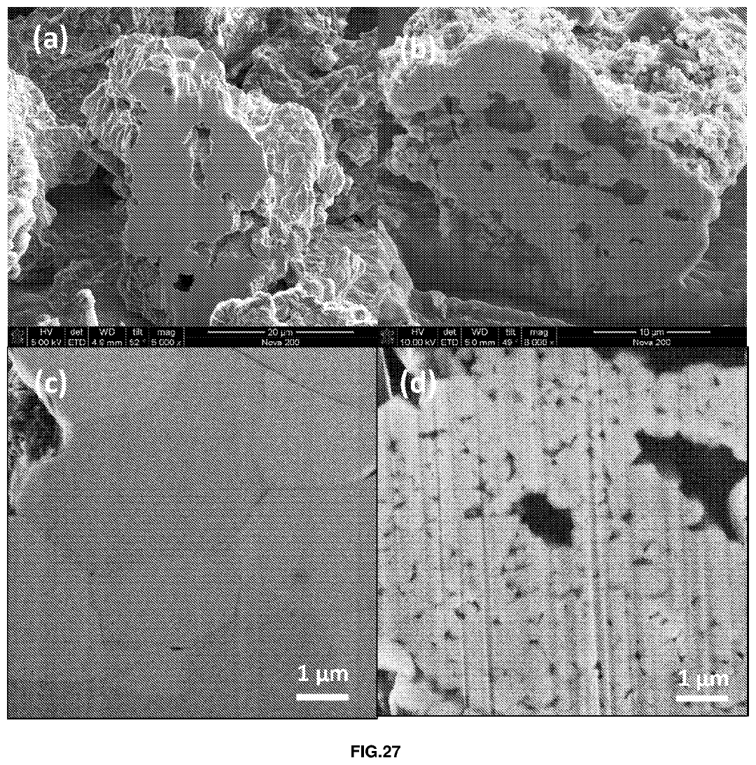

FIG. 27 (a) and (c) the SEM profile of LiNiO₂ powders before cycling and (b) and (d) the SEM profile of LiNiO₂ powders after 100th cycling; and

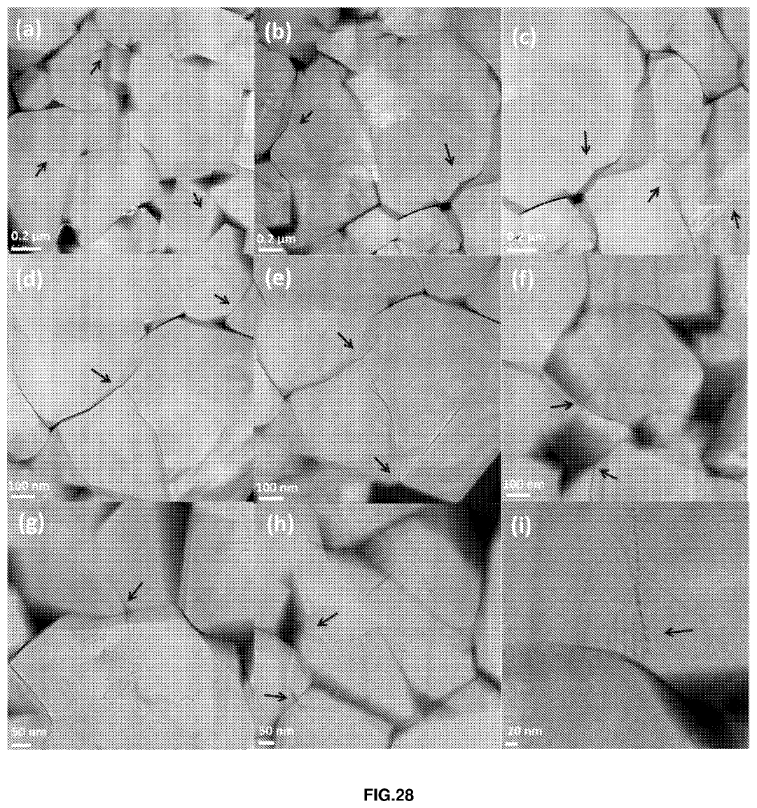

FIG. 28 TEM characterization of LiNiO₂ particles after 100^{th} cycling with different resolutions corresponding calibration bars of: (a) (b) (c) 0.2 μm (d) (e) (f) 100 nm and (g) (h) (i) 50 nm, where the figures show evidence of high density of intragranular cracks and their connections between intergranular cracks, highlighted with arrows.

### DETAILED DESCRIPTION

As part of the present disclosure we have discovered that problems with existing cathode materials and cathode electrode designs originate substantially from the non-stable surface oxygen atoms of cathode powders that leads to surface phase degradation, while the bulk phase remains stable. Based on our discovery, we propose cathode compositions and methods to specifically stabilize the LiNiO₂ surface phase through a surface cathode coating layer with a controlled thickness of sub-nano to nano scale, and leave the bulk phase unaltered. An important property of the coating layer is to provide strong bonding to surface oxygen atoms to block surface oxygen evolution, and thus inhibit surface phase transitions, while also allowing rapid Li ion and electron transportation there-through. As further disclosed herein, embodiments of the surface cathode coating layer can be engineered, via ALD, post ALD annealing and lanthanide atom doping procedures, to facilitate providing physically separate electron and Li ion conduction pathways through the coating layer, such that the Li ions and electrons do not meet outside of the cathode composition, and e.g., form undesired Li-containing dendrites structures at the outer surface of the coating layer which can reduce battery charge/discharge capacity.

One embodiment of the disclosure is a cathode composition.

FIG. 1 presents a schematic representation of a cross-sectional view of a cathode composition 100 of the disclosure. FIG. 2 (A) presents another schematic representation of the cathode composition 100 analogous to that depicted in FIG. 1 of the disclosure, and, FIG. 2(B) presents a detailed view schematic representation of a portion of a surface cathode coating layer of the cathode composition before and after a thermal anneal.

With continuing reference to FIGS. 1-2B throughout, the composition 100 includes a core cathode body 110, the core cathode body composed of nickel oxide crystallite particles.

The term, nickel oxide crystallite particles, as used herein refers to the core cathode body 110 including, or in some embodiments, consisting of primary particles of lithium nickel oxide (e.g., primary particles 112) having a size (e.g., an average diameter in the composition 100) in a range of about 0.1 to 0.3 micron, with groups of the primary particle aggregated together to form larger secondary particles (e.g., secondary particle 115) having a size (e.g., an average diameter in the composition) in a range from about 5 to 20 microns. Adjacent aggregated ones of the primary particles 112 and aggregated ones of the secondary particles 115 can be interconnected via a nickel-oxygen or nickel-fluoride bonding network.

The term “composed of” as used herein means at least about 90 to 100 mol % of the core cathode body consists essentially of the nickel oxide depending on the state of charge/discharge of the core cathode body, with the balance being substantially Li⁺ ions. For example in a battery environment, if fully charged, the composition of the core cathode body can have a chemical formula of Li_{0.07}NiO₂ with about 99 to 100 mol % NiO₂ and about 7 mol % Li, while in a in a fully discharged state or in a pre-battery packaging state, with Li⁺ ions present, the composition of the core cathode body can have a chemical formula of Li_{1.0}NiO₂ with about 99 to 100 mol % NiO₂ and about 99 to 100 mol % Li.

In some embodiments, the nickel oxide of the core cathode body can includes up to 30 mol % of a non-nickel first row transition metal or a post-transition metal, e.g., to help further stabilize the core cathode body against surface oxygen evolution. For instance, the nickel oxide can have a chemical formula of Ni₁₋ₓMₓO₂ where M is one or more non-nickel first row transition metal or a post-transition metal and x≤0.3. As non-limiting examples M can be one or more of Mn, Co, Zn or Al atoms. In some such embodiments, e.g., at x≤0.2 (e.g., Ni_{0.85}Co_{0.075}Mn_{0.075}O₂) we believe the need for a surface coating layer is particularly important because the other included metal, M, may no longer be able to fully uniformly mix with the Ni and therefore may not provide the desired level of stabilization.

As further illustrated in FIGS. 1-2B, the composition 100 also includes a surface cathode coating layer 120. The coating layer 120 contacts and at least partially surrounds an outer surface 125 of the core cathode body 110.

Embodiments of the core cathode body 110 can be a substantially internal structure, with the body 110 being contacted on all sides by the surface cathode coating layer 120 such that, e.g., in a battery environment, only small surface area portions (e.g., 20%, 10% or 5% or less of the total area of the outer surface 125 of the body 110 not covered by the coating layer 120), or substantially none (e.g., 1% or less of the total area of the outer surface 125 of the body 110 not covered by the coating layer 120), of the core cathode body is not covered by the coating layer 120 such that the surface cathode coating layer 120 substantially entirely surrounds the core cathode body 110.

Embodiments of the surface cathode coating layer can include one or more of a transition metal or post-transition metal oxide or fluoride. The transition metal or post-transition metal oxide can be any oxide or any fluoride of any transition metal element or post-transition metal element. As non-limiting examples, in some embodiments, the transition metal or post-transition metal oxide can be or include one or more of TiO₂, ZnO, ZrO₂, HfO₂ or Al₂O₃. As non-limiting examples, in some embodiments, the transition metal or post-transition metal fluoride can be or include one or more of FeF₂, CuF₂, or AlF₃.

Embodiments of the surface cathode coating layer can include one or more lanthanide row atoms having a concentration in a range from about 0.1 to 10 mol %, e.g., to help adjust the conduction of electrons and Li ions as further discussed below. In various embodiments of the coating layer, the total concentration of lanthanide row atoms can be in a range from about 0.1 to 0.5, 0.5 to 1, 1 to 2, 2 to 3, 3 to 4, 4 to 5, 5 to 6, 6 to 7, 7 to 8, 8 to, 9, 9 to 10, 0.1 to 5, 5 to 10, 0.1 to 2.5, 2.6 to 5.0, 5.1 to 7.5, or 7.6 to 10.0 mol %. As non-limiting examples, in some embodiments, lanthanide row atoms can be or include one or more of La, Ce, Sm or Gd.

Embodiments of the surface cathode coating layer can have a thickness 130 (e.g., an average thickness in the composition) in a range from about 0.5 to 30 nm. For instance, in some embodiments, the thickness 130 can be about 0.5, 1, 2, 3, 4, 5, 6, 7, 8, 9, 10, 15, 20, 25 or 30 nm.

In some embodiments, having thickness 130 of 10 nm or less is conducive to allow rapid e− and Li ion conduction while thickness of greater than 10 nm may impede conduction. Having thickness of less than 0.5 nm can be difficult to apply uniformly around the core cathode body and therefore the reliability of stabilizing the core cathode body surface and/or e− and Li ion conduction can be less than desired.

The ALD procedure disclosed herein can advantageously apply sub nm thick portions of the coating layer to form a highly uniform conformal coating layer 120 around of the core cathode body can be attained. In some embodiments for instance, the thickness of the ALD-formed coating layer surrounding the core cathode body can be highly uniform, e.g., having a thickness variation of ±20%, ±10%, ±5%, ±1% or less for various embodiments of the composition 100.

The surface cathode coating layer can have an amorphous, polycrystalline or composite amorphous/polycrystalline atomic structure. As illustrated, the surface cathode coating layer can have grains 135 of such atomic structures, e.g., a plurality of grains having amorphous or crystallite or semi-crystalline (e.g., composite amorphous/polycrystalline) atomic structures. As, illustrated the plurality of grains 135 form irregular grain boundaries 140 at the interfaces between adjacent ones of the grains 135 in the coating layer 120 such that the plurality of grains 135 and the grain boundaries 140 at least partially surround the outer surface 125 of the core cathode body 110.

As schematically illustrated in FIG. 2B, while not limiting the scope of the disclosure by theoretical considerations, in some embodiments, the ALD procedure can result in the formation of a coating layer 120 with a substantially amorphous atomic structure (e.g., 80, 90, 95% or greater amorphous atomic structures as determined by XRD). We further believe that the post-ALD thermal treatment procedure such as disclosed herein can be applied to advantageously control the extent crystallinity of grains 135 in the coating layer 120. That is, the post-ALD thermal treatment can be used to make the ALD-formed coating layer 120 substantially more polycrystalline (e.g., 80, 90, 95% or greater crystalline atomic structures as determined by XRD) or partially polycrystalline (e.g., greater than 20 to less than 80% crystalline and balance amorphous atomic structures) than the original ALD-formed coating layer 120, depending on how the thermal treatment is applied.

We further believe that oxide and fluoride crystallites of the transition or post-transition metals can promote Li ion conduction there-through while the formation of grain boundaries 140 of such crystallites facilitates the conduction of electrons through the grain boundaries 140, to thereby provide the desired separate pathways for Li ion and electron conduction though the coating layer. It is further believed that such crystallites grains 135 may facilitate the migration of lanthanide atoms towards the grain boundaries 140, e.g., during the ALD procedure or during the post-ALD thermal anneal procedure. The further believe that the formation of crystallite grain boundaries with a bulk of the lanthanide atoms at such grain boundaries may result in a positively charge environment in the vicinity of the grain boundaries (e.g., FIG. 1, positively charges lanthanide atoms, “+”, within 100 s Ås of the grain boundaries). Such a positively charged environment may in turn repel Li ions away from the grain boundaries and attract electrons towards the grain boundaries.

FIG. 3 presents a schematic representation of a cross-section view of a battery assembly 300 that includes the cathode composition 100. As illustrated in FIG. 3, the cathode composition 100 can form part of a cathode electrode structure 310 in the lithium ion battery assembly 300.

As illustrated in some embodiments the cathode composition 100 in the cathode electrode structure 310 can form, or be formed into, a plurality of layers (e.g., layers 315) where the layers are separated from each other by an electrolyte medium that include lithium ions (e.g., electrolyte medium 320, e.g., 1.0 M LiPF₆ organic electrolyte).

As illustrated embodiments of the battery assembly 300 can further includes an anode electrode structure 325 and a separation barrier 330 (e.g., a polymer membrane separator) located between the cathode electrode structure 310 and the anode electrode structure 325. The battery assembly 300 can include electrical components (wire, switch and resistor components 335) attached to the cathode and anode electrode structures 310, 325 as familiar to those of ordinary skill. The cathode and anode electrode structures 310, 325 can include a contact structures (e.g., an Al cathode contact structure 340 and a Cu anode contact structure 345) that couple the electrical components 335 to these electrode structures 310, 325.

In some embodiments, the battery assembly 300 is configured as an electrical power supply for a vehicle, e.g., land-, water- or air-born vehicles such as automobiles, boats, drones or planes or other vehicles, or, as an electrical power supply for other electric devices, as familiar to those of ordinary skill.

In some such battery environments, in the presence of the Li ion containing electrolyte medium and in a fully charged state (e.g., a charged state achieved by applying a 0.1 C current rate with a cutoff voltage of 4.3 V), the core cathode body can have has a chemical formula of Li₁₋ₓNiO₂, where x≥0.7, ≥0.8, ≥0.9 or ≥0.99.

As noted, the surface coating layer helps block surface oxygen evolution and loss from the core cathode body. For instance, in some battery environments, a mole ratio of Ni:O at a outer surface of the core cathode body 100 (e.g., within about 15 or 10 nm of the outer surface 125 of the core cathode body 100, as measured by XPS), after at least 100, or 200, or 300 charge-discharge cycles of the cathode electrode structure 310, can be within about 30, 20, 10 or 5 percent, of the mole ratio of Ni:O at the outer surface of the core cathode body before the charge-discharge cycles.

Another embodiment is method of manufacture. FIG. 4 presents a flow diagram of example method of manufacture 400 embodiments of the disclosure.

With continuing reference to FIGS. 1-4 throughout, the method 400 includes, preparing a cathode composition (e.g., step 410, cathode composition 100), such as any embodiments of the cathode composition disclosed herein.

Preparing the cathode composition (step 410) can include forming a core cathode body (e.g., step 420, core cathode body 110), the core cathode body composed of nickel oxide crystallite particles, such as discussed in the context of FIGS. 1-3. Non-limiting examples of preparing the core cathode body 110 are presented in the Experimental Results section of the disclosure herein.

Preparing the cathode composition (step 410) can include forming, by ALD, a surface cathode coating layer (e.g., step 430, surface cathode coating layer 120) contacting and at least partially surrounding an outer surface of the core cathode body (e.g., outer surface 125). The surface cathode coating layer formed in step 430 can include one or more of a transition metal or post-transition metal oxide or fluoride and one or more lanthanide row atoms having a concentration in a range from about 0.1 to 10 mol %, have a thickness (e.g., thickness 130) in a range from about 0.5 to 30 nm, and have an amorphous, polycrystalline or composite amorphous/polycrystalline atomic structure.

In some such embodiments, forming the surface cathode coating layer (step 430) includes repeatedly sequentially exposing the outer surface of the core cathode body to gaseous deposition precursors of the transition metal or the post-transition metal, the oxide or the fluoride and the lanthanide row atoms.

The ALD applied in step 430 can include cyclic repetition of two steps of metal precursor surface adsorption (a 1st half-cycle) and oxidant (O) or fluoride (F) reaction (a 2nd half-cycle). One full cycle of ALD adds about 0.2-0.3 atomic layers of metal oxide or fluoride on the core cathode body surface 125, and therefore it takes about 3 to 5 full ALD cycles to add one atomic layer of metal oxide or fluoride.

By controlling the total number of cycles, the thickness of metal oxide or fluoride coating layer can be fine-tuned with sub-monolayer accuracy. This fine-tuning control is in contrast to chemical vapor deposition or wet chemistry deposition process which we expect would result in a more uneven thickness of coating layer being formed (e.g., ±50, 100 percent or greater thickness variations), and therefore unpredictable degrees of stabilization of the core cathode body and/or unpredictable conductive properties of the cathode composition.

As non-limiting examples, in some embodiments, the transition metal or post-transition metal oxide of the surface cathode coating layer can be one or more of TiO₂, ZnO, ZrO₂, HfO₂ or Al₂O₃ and the precursor gases of Ti, Zn, Zr, Hf and Al are TiCl₄, Diethylzinc, TEMA-Zr, TEMA-Hf and Trimethylaluminum, respectively, and the precursor gas for the O are O₂, H₂O, O₃ or mixtures thereof. In some embodiments, the transition metal or post-transition metal fluoride of the surface cathode coating layer can be one or more of FeF₂, CuF₂, or AlF₃ the precursor gases of Fe, Cu, and Al are Fe(CO)₅, Cu(OCHMeCH₂NMe₂)₂, and Trimethylaluminum, respectively, and the precursor gas for the fluoride is HF. In some embodiments, the transition metal or post-transition metal fluoride of the surface cathode coating layer can be one or more of ZrF₄, MnF₂, HfF₄, MgF₂, and ZnF₂ and the precursor gases of Zr, Mn, HF and Zn are tetrakis(ethylmethylamido) zirconium, Bis(pentamethylcyclopentadienyl)manganese(II), TEMA-Hf, and Diethylzinc, respectively, and the precursor gas for the fluoride is HF. In some embodiments, the lanthanide row atoms of the surface cathode coating layer is one or more of La, Ce, Sm or Gd and the precursor gases are La(C₅H₅)₃, Ce(iPrCp)₂(N-iPr-amd), C₂₇H₃₉Sm and C₂₇H₃₉Gd respectively.

In some embodiments, the repeated sequential exposing of the ALD in step 430 can be performed at a temperature value in a range from 50 to 600° C. at cycling rates from 0.2 to 0.3 nm atomic layer per cycle for 2 to 50 cycles to provide the desired thickness (e.g., FIG. 1, thickness 130) in the range from about 0.5 to 30 nm. In some embodiments, the ALD in step 430 is performed at a temperature value of about 50, 100, 150, 200, 250, 300, 350, 400, 450, 500, 550 or 600° C.

In some embodiments, the repeated sequential exposing of the ALD in step 430 results in the coating layer contacting about 80 percent or more of the outer surface of the core cathode body.

As further illustrated in FIG. 4, some embodiments of the method 400 can further include, after forming the core cathode body and the surface cathode coating layer, applying a post-ALD thermal anneal (step 440), the anneal including a temperature value in a range from range from 200 to 900° C. for a time interval in a range from 1 to 24 hours. In some embodiments, e.g., the post-ALD anneal in step 440 is performed at a temperature value of about 200, 300, 400, 500, 600, 700, 800, or 900° C. for about 1, 2, 3, 4, 5, 6, 7, 8, 9 10, 11, 12, 13 14, 15, 16, 17, 18, 19, 20, 21, 22, 23, or 24 hours. As noted elsewhere herein, the post-ALD anneal is believed to help convert an ALD-formed amorphous surface coating layer into a polycrystalline or partial polycrystalline surface coating layer.

As further illustrated in FIG. 4, some embodiments of the method 400 can further include assembling the cathode composition as a plurality of layers in a cathode electrode structure (e.g., step 450, layers 320, cathode electrode structure 310 of battery assembly 300) where the layers are separated from each other by an electrolyte medium including lithium ions (e.g., medium 320).

Experimental Results

Example embodiments of the disclosure are presented to demonstrate various aspects of the cathode composition and the method as disclosed herein.

Procedures for the ALD deposition of Al₂O₃, for use as a surface cathode coating layer, were investigated by depositing via ALD, an Al₂O₃ film on a silicon wafer. The ALD deposition conditions included Al₂O₃ inorganic nanolayers deposited. Each ALD cycle consisted of 20 s TMA exposure, 60 s Ar purge, 20 s H₂O exposure, and 100 s Ar purge. TMA and H₂O, used as ALD precursors, were evaporated at 20° C.

FIG. 5A shows an SEM surface image of an Al₂O₃ film and FIG. B shows a height profile of a portion of the Al₂O₃ film. Al₂O₃ films formed as described above were then subject to a post-ALD thermal anneal. The post-ALD thermal anneal included exposing the Al₂O₃ film to a temperature of 600° C. for 6 hr in air. Other post-ALD thermal anneal conditions included annealing temperature values in a range from 400 to 900° C. for 2-24 hrs in air, reducing or inert atmosphere.

FIG. 5C shows a SEM surface image of the Al₂O₃ film after the post ALD thermal anneal and FIG. 5D shows a height profile of a portion of the Al₂O₃ after the post ALD thermal anneal. FIG. 6 shows a XRD profile of the Al₂O₃ film after the post ALD thermal anneal. These results suggest that while the post ALD thermal anneal conditions investigated increased the surface roughness of the Al₂O₃ film, there was not evidence of a crystalline phase.

Procedures for the ALD deposition of TiO₂, for use as a surface cathode coating layer, were investigated by depositing via ALD, a TiO₂ film on a silicon wafer. The ALD deposition conditions included TiCl₄/H₂O cycles at a temperature value in a range from 100 to 600° C. with 0.5 Å/cycle growth rate

FIG. 7A shows an SEM surface image of a TiO₂ film and FIG. B shows a height profile of a portion of the TiO₂ film. TiO₂ film formed as described above were then subject to a post-ALD thermal anneal. The post-ALD thermal anneal included exposing the TiO₂ film to a temperature of 600° C. for 2 hr in air. Other post-ALD thermal anneal conditions include an annealing temperature value in a range from 400 to 900° C. for 2 to 24 hrs in air, reducing or inert atmospheres. FIG. 7C shows a SEM surface image of the TiO₂ film after the post ALD thermal anneal and FIG. 7D shows height profile of a portion of the TiO₂ film after the post ALD thermal anneal. These results suggest that that TiO₂ film has grain growth toward polycrystalline thin film textures.

Procedures for the ALD deposition of ZnO (e.g., as polycrystalline and amorphous ZnO nanolayers) for use as a surface cathode coating layer, were investigated by depositing via ALD, a ZnO film on a silicon wafer. The ALD deposition conditions included 20 s exposure to diethylzine (DEZ, Aldrich, Zn 52 wt %), exposure for 60 s to an Ar purge, 20 s exposure to H₂O, and exposure for 100 s to an Ar purge. DEZ and H₂O, used as ALD precursors, were evaporated at 20° C. For polycrystalline and amorphous ZnO nanolayers. The ALD procedure to form polycrystalline ZnO nanolayers was conducted at high temperatures, above 250° C., and the ALD procedure to form amorphous ZnO nanolayers was conducted at low temperature, below 50° C.

FIG. 8A shows a height profile from a SEM surface image of a portion of a ZnO film and FIG. 8B shows a XRD profile of the ZnO film formed by ALD with Ar to provide poor O₂ conditions. FIG. 8C shows a height profile from a SEM surface image of a portion of a ZnO film and FIG. 8D shows a XRD profile of the ZnO film formed by ALD with O₂ to provide rich O₂ conditions. These results show how the crystallinity of ALD formed ZnO films can be adjusted by controlling the composition of the ALD precursors. These results suggest that other than heat treatment, defect control can be another way of controlling coating layer conductivity.

To demonstrate how the surface cathode coating layer could be shown to prevent the loss of surface oxygen after charge/discharge cycling, XRD and EDS measurements were made of LiNiO₂ powder (e.g., formed as described herein in section 3, Experimental Section herein). FIG. 9A shows a XRD profile of the LiNiO₂ powder, FIG. 9B shows an XPS profile of the LiNiO₂ powder and FIG. 9C shows a detailed view of a portion of the XPS profile shown in FIG. 9B. The XRD measurements and profile can be used to measure Ni:O ratios at micron depths in the LiNiO₂ powder, while the EDS measurements and profile can be used to measure Ni:O ratios at several nanometer depths in the LiNiO₂ powder. Thus, the ability of the surface cathode coating layer to prevent or decrease surface oxygen loss from the LiNiO₂ powder can be characterized by comparing the relative changes in Ni:O ratios before and after charge/discharge cycling.

Capacity degradation by phase changes and oxygen evolution has been the largest obstacle for the ultimate commercialization of high-capacity LiNiO₂-based cathode materials. The ultimate thermodynamic and kinetic reasons of these limitations are not yet systematically studied, and the fundamental mechanisms are still poorly understood. In this work, both phenomena are studied by density functional theory simulations and validation experiments. It is found that during delithiation of LiNiO₂, decreased oxygen reduction induces a strong thermodynamic driving force for oxygen evolution in bulk. However, oxygen evolution is kinetically prohibited in the bulk phase due to a large oxygen migration kinetic barrier (2.4 eV). In contrast, surface regions provide a larger space for oxygen migration leading to facile oxygen evolution. These theoretical results are validated by experimental studies, and the kinetic stability of bulk LiNiO₃ is clearly confirmed. Based on these findings, a rational design strategy for protective surface coating is proposed.

I. Introduction. The wide application of Li-ion batteries (LIB) in the energy storage fields of smart grid, portable electronic devices and, especially, in the automotive industry, has largely promoted the renaissance of electrochemistry research. In the past two decades, LiCoO₂ has dominated the LIB market as the predominant commercial cathode material. However, due to its limited reversible charge capacity of around 145 mA h g⁻¹, as well as the high material cost, a substitution of Co with Ni and other elements in LiCoO₂ has undergone active research in the quest for effective approaches to increase the capacity with reduced cost. This metal substitution approach gave rise to the nickel-based layered oxides (LiNi₁₋ₓMₓO₂, M=Co, Mn, Al, etc.), which have achieved a great commercial success in recent years, as shown by LiNi_{1/3}Co_{1/3}Mn_{1/3}O₂ (NCM111), LiNi_{0.5}Co_{0.2}Mn_{0.3}O₂ (NCM523), and LiNi_{0.8}Co_{0.15}Al_{0.05}O₂ (NCA), with larger practical charge capacities of 160-180 mA h g⁻¹.^{[1-4]} However, to meet an increasing demand of LIB with an energy density above 300 W h kg⁻¹ for electrical vehicles with a 300-plus mile range, the development of LiNiO₂-based layered oxides (LiNi₁₋ₓMₓO₂, x>90%) has spurred wide research efforts. These materials can deliver a specific charge capacity over 200 mA h g⁻¹, benefiting from a lower voltage window of LiNiO₂ (3.5-4.3 V).

However, LiNiO₂-based layered oxides are known to experience severe oxygen evolution and capacity degradation during cycling, which constitute the bottlenecks in their ultimate commercialization. Previous research works comparing different layered oxide cathode materials have revealed that higher Ni concentration always leads to poorer thermal stability with easier oxygen evolution at elevated temperatures.^{[3,5,6]} Early studies on thermal stability of charged LiNiO₂ (i.e., dethithated Li_{y}NiO₂ with y<0.5) have detected oxygen gas formation at emerging temperatures of 100-200° C. Furthermore, the emerging temperature can be even lower at larger depths of charge (e.g., Li_{0.25}NiO₂ corresponding to ≈200 mA h g⁻¹ capacity).^{[7,8]} Furthermore, O₂ can even be released after initial charging of Ni-rich oxides (before significant temperature increase), which results in surface porosity, spinel and rocksalt phase formation.^{[9,10]} Along with oxygen evolution, fast capacity degradation of LiNiO₂-based cathode materials was widely reported.^{[11-13]} The reported degree of capacity degradation after 100 charging/discharging cycles ranges from 40 to 80%, depending on the synthesis method, particle size and morphology, current density, cutoff voltage, and other experimental conditions.^{[11-13]}

Nevertheless, there is a lack of consensus about whether the phase transition and oxygen evolution originate from the surface or bulk of LiNiO₂-based cathode.^{[14]} The phase transitions from layered to spinel and finally to rocksalt structures have been reported, and oxygen evolution is closely related with such phase transitions due to the different Ni/O stoichiometry between layered LiNiO₂ and rocksalt NiO.^{[6,9,10,15]} At the surface of layered oxides, carbonaceous molecular species and fluorine-based Li salts in the electrolyte can react with the cathode powder surface, which can induce undesirable interface phase formation or accelerate the oxide phase transition at surface.^{[16-18]} However, the bulk phase transformation could be another mechanism, in which case the phase change is not limited to surface regions, but penetrated into or even started from the bulk regions. The thermodynamic basis of phase change has been well established for Li-rich layered oxides due to energetically favorable cation and anion diffusions during electrochemical cycling.^{[14,19,20]}

Nevertheless, the initiation mechanisms for oxygen evolution and oxide phase transitions have not been well understood, yet.^{[14]} Specifically, it is critical to understand the fundamental reason why LiNiO₂-based oxides become more easily suffering from oxygen evolution than other layered oxides. To answer these key questions and help facilitate materials design of improved LiNiO₂-based cathode materials, a systematic fundamental study on the thermodynamics and kinetics of oxygen evolution and capacity degradation, especially at atomic scale, would be very instructive. In this work, density functional theory (DFT) method was used to understand the atomic and electronic-scale mechanisms of oxygen evolution and phase transition in LiNiO₂ upon charging. In contrast to most theoretical works, which only address thermodynamic and bulk phase chemistry and physics, both thermodynamic and kinetic phenomena involved in bulk and surface phase transitions have been addressed in this work. Furthermore, the theoretical findings were validated by battery experiment using LiNiO₂ cathodes. Based on the obtained theoretical and experimental results, we discuss possible mechanisms for the capacity degradation upon cycling and the material design principles for LiNiO₂-based cathode materials stabilization.

2. Results and Discussion 2.1. Thermodynamic Study of Oxygen Evolution. We initiate our modeling study by analyzing the thermodynamics of oxygen evolution in bulk LiNiO₂. As aforementioned, oxygen evolution during heating and cycling has been widely reported by different experiments. To understand the correlation between oxygen evolution and delithiation, we have first calculated the oxygen vacancy formation energy as a function of depth of charging by incrementally removing Li from LiNiO₂. Stable intermediate states (corresponding to optimized Li configurations) during delithiation of LiNiO₂ were determined using cluster expansion method as described in the Supporting Information (FIG. 17, Supporting Information). The oxygen vacancy formation energy at each intermediate state was calculated following Equation (1) in the Experimental section, and presented in FIG. 10a. Before charging, that is, for fully lithiated LiNiO₂, the oxygen vacancy formation is 1.8 eV. However, upon delithiation, the formation energy decreases rapidly.

When half of Li is extracted, the formation energy is reduced to about 0.9 eV, and when 75% Li is removed, the formation energy becomes as low as 0.35 eV. The equilibrium oxygen vacancy concentration can be estimated from Equations (2) and (3). FIG. 10b shows that 75% delithiation (i.e., Li_{0.25}NiO₂) increases the equilibrium oxygen vacancy concentration by 10⁴ times with respect to the 50% delithiated LiNiO₂, and 10¹¹ times with respect to the fully lithiated LiNiO₂. Note that these results are based on equilibrium condition, and at low temperature, the equilibrium cannot be reached for kinetics reasons. The kinetics will be discussed in the following sections. However, high-temperature analysis like differential scanning calorimetry (DSC) results has indicated that oxygen evolution in Li_{0.3}NiO₂ has a peak at about 500 K,^{[21]} consistent with the diagram presented in FIG. 10, which shows that the vacancy concentration can reach more than 0.1 per formula unit (f.u.) at 500 K. Note that this calculation is based on an air environment, in which the oxygen partial pressure is 0.2 atm. When the cathode material is placed in a more reductive environment with reduced oxygen partial pressure, the oxygen evolution emerging temperature is shifted to even lower values. As shown in FIG. 18 (Supporting Information), when the oxygen partial pressure is reduced from 0.2 to 10⁻⁵ atm, the required temperature to achieve the vacancy concentration of 0.1 f.u.⁻¹ decreases from 500 K (277° C.) to 370 K (97° C.). Since in the assembled LIB, the LiNiO₂ cathode is immersed in organic liquid electrolyte with LiPF₆ salts, the cathode is actually in a low oxygen partial pressure environment, and the calculated results show the underlying thermodynamic basis why oxygen evolution at elevated temperatures would be a major safety concern. Note that, as shown in FIG. 10a, 75% of Li extraction implies a charging capacity of 210 mAh g⁻¹. Therefore, in meeting the capacity requirement of 200 mAh g⁻¹ or higher in LiNiO₂-based cathode materials, the bulk oxygen evolution problem represents a fundamental challenge in thermodynamic instability of layered oxides.

By tracing the calculated Bader charges and magnetic moments of oxygen ions in LiNiO₂ during delithiation, an evidence of anionic redox reaction has been identified. As plotted in FIGS. 10c,d, the Bader charge of oxygen increases from −1.2 e⁻ to −0.8 e⁻, at the same time the magnetic moment increases from 0.04 to 0.12 μB. Such increases are almost linear during the delithiation, similar to the oxygen vacancy formation energy. Therefore, when Li is removed from the oxide system, not only Ni cations (i.e., Ni³⁺ to Ni⁴⁺), but also oxygen anions are involved in the redox reactions: that is, oxygen ions are also less reduced. Such decreased reduction of O corresponds to a bonding character change such that Ni—O bonds in delithiated LiNiO₂ become more covalent than that in fully lithiated LiNiO₂.

As explained below, there exists a strong correlation between metal-oxygen binding strength and bonding covalency. To illustrate this relationship, we have compared the oxygen vacancy formation energies of a series of lithiated 3d transition metal (Me) layered oxides with the same stoichiometry of LiMeO₂. FIG. 11a shows that the oxygen vacancy formation energy decreases almost linearly from early to late 3d Me. The vacancy formation energy in LiVO₂ is as high as 6.5 eV, whereas that of LiCuO₂ is only 1.1 eV. LiMnO₂ and LiCoO₂ are exceptions from the linear sequence with lower and higher vacancy formation energies than the linear trend. These deviations can be explained by the Jahn-Teller distortions of Me-O octahedral which only happen in LiMnO₂ and LiCoO₂₋ₓ, before and after the O removal, respectively. As illustrated in FIG. 11b, when an oxygen vacancy is formed, two electrons are released to the system (i.e., O²⁻ leaves as O), reducing the neighboring cations. The preexisting Jahn-Teller distortion of the neighboring Mn³⁺—O octahedron in LiMnO₂ is then diminished after Mn³⁺ is reduced to Mn²⁺, leading to less stable oxide system corresponding to the reduced oxygen vacancy formation energy. On the contrary, the released electrons can reduce Co³⁺ in LiCoO₂ to the Jahn-Teller distorted Co²⁺—O octahedron in LiCoO₂₋ₓ, which further stabilizes the oxide system energy corresponding to the increased oxygen vacancy formation energy. Consequently, the energy differences from Jahn-Teller lattice distortions introduce deviations from the linear sequence, as shown in FIG. 11a. Nevertheless, the overall linear trend of vacancy formation energy decrease from LiVO₂ to LiCuO₂ is evident. From a traditional point of view, all the transition metal cations in the LiMeO₂ series have the same nominal oxidation state of 3⁺, since Li and O are viewed as purely ionic with oxidation states of 1+ and 2−, respectively. However, a more realistic Bader charge distribution analysis reveals the difference among different transition metal cations. From LiVO₂ to LiCuO₂, the Bader charge of transition metal decreases from 2.05 e⁻ to 1.3 e⁻ (see FIG. 11c). Correspondingly, the Bader charge of oxygen increases from −1.53 e⁻ to −1.15 e⁻ (see FIG. 11d). This change is a clear indication of a transition from “more-ionic” to “more-covalent” Me-O bonds from early 3d to late 3d transition metal oxides. Intrinsically, this trend stems from the mixed ionic/covalent nature of transition metal-oxygen bonding. This trend can also be well understood from bonding orbital theory. FIG. 11e gives the calculated bonding orbital energy level of each isolated atom. In these calculations, metallic atoms lose electrons when forming oxide, their energy level corresponds to highest occupied molecular orbital (HOMO). And for oxygen atom which gains electrons when forming oxide, it refers to the lowest unoccupied molecular orbital (LUMO). From early 3d to late 3d transition metals, the energy level difference with respect to the oxygen atom (Δχ) consistently decreases. As illustrated in FIG. 11f, a smaller Δχ for late 3d metal gives rise to higher bonding state ψ and lower antibonding state ψ*, and the resulting bond tends to be more covalent. Normally, stronger Me-O covalence corresponds to smaller bandgap. This electronic structure change promotes the formation of oxygen vacancies, since after the loss of a neutral oxygen atom, two remaining electrons can more easily occupy lower energy antibonding states of neighboring Me-O bonds. This conclusion is consistent with a related work by Henkelman and co-workers on oxygen stability in Li-rich layered oxides, where they found that Ti lifts the antibonding state and increases the bandgap, thus suppressing oxygen loss.^{[22]}

Therefore, the weak metal-oxygen binding energy in delithiated LiNiO₂ originates from the “more-covalent” bonding nature of Ni—O. This analysis also provides an insight on the underlying reasons why most commercialized Ni-based cathode materials (NCA, NCM, etc.) are empirically stabilized by alloying with stronger oxygen bonding metal cations, like Mn, Co, Ti, Al, etc. These cations normally increase the ionic composition for metal-oxygen bonding, thus increasing the oxygen binding strength (leading to larger oxygen vacancy formation energy). Very recently, Yabuuchi et al. reported that by replacing Nb with less covalent Mn⁴⁺, the oxygen stability of Li₃NbO₄ can be effectively increased.^{[23]} Their finding is also consistent with our conclusion that the increasing covalent character in metal-oxygen bonding through decreasing oxygen reduction would facilitate oxygen evolution. This strong correlation is present because the redox reaction during charging/discharging is no longer limited to metal cation oxidation state changes, but also includes the coupling between cations and anions. In other words, both cations and anions are involved in the redox reaction, leading to oxygen instability. Another work by Lee and Persson on Li—Mn-rich Li₂MnO₃ has reached a similar conclusion on decreased oxygen reduction.^{[24]} Since Mn⁴⁺ cannot be further oxidized to Mn⁵⁺, upon deep charging of Li₂MnO₃, remarkable oxygen evolution is observed as a consequence of decreased reduction of O²⁻ to less stable O⁻ (known as labile oxygen redox activity).^{[25,26]}

Additionally, our results also suggest that LiCuO₂ would face even more severe oxygen evolution issues than LiNiO₂. Recently, the Li—Cu—O system has been proposed as a promising cathode material candidate benefiting from the high voltage of the Cu²⁺/Cu³⁺ redox couple. However, as expected from the current analysis, oxygen is not stable during deep charging of Li—Cu—O leading to the formation of CuO and O₂.^{[27,28]} DFT simulations on this system have suggested that the participation of oxygen in the redox chemistry destabilizes the lattice and leads to oxygen gas evolution at high voltages (3.7 V vs Li/Li⁺).^{[29]} Combined with our analysis shown in FIG. 11a-f, the covalent Cu—O bonding nature is the main reason behind such easy oxygen evolution, and a possible way of stabilizing LiCuO₂ would be bulk doping or alloying with cations that can form more ionic Me-O bonds, similar to metal alloying in Ni-based cathode materials.

2.2. Oxygen Evolution Induced Phase Transition. Earlier theoretical works on Li-rich layered oxides revealed a close relationship between oxygen vacancy formation and transition metal migration. As reported by Qian et al., a neighboring oxygen vacancy would reduce the Ni migration barrier from 1 to 0.25 eV in Li—Mn-rich NCM oxides.^{[30]} Lee and Persson also found that oxygen loss could open new cation migration paths with almost zero energy barrier.^{[24]} Clearly, such oxygen vacancy driven cation migration contributes to the formation of spinel-like domains which could act as nuclei for subsequent layered-spinel-rocksalt phase transitions.^{[24,6]} Once rocksalt phases are formed, Li diffusion pathways will be blocked. Motivated by these theoretical findings for Li-rich layered oxides, we have explored the effect of oxygen vacancies on Ni migration in LiNiO₂. As shown in FIG. 12a, the model is examining the Ni migration from the original octahedral sites in transition metal layers to neighboring tetrahedral sites in the Li layer, with LiNiO₂ in the half-delithiated electrochemical state. The calculated migration barriers with and without oxygen vacancies are plotted in FIG. 12b. Formation of oxygen vacancy induces a reduction of the neighboring Ni atom, which shows reduced charge state by 0.43 e⁻ from Bader charge analysis as illustrated in FIG. 19 (Supporting Information). For pristine Li_{0.5}NiO₂ without oxygen vacancies, the diffusion barrier is as high as 1.6 eV, indicating the high resistance for Ni migration. However, the formation of oxygen vacancies introduces a strong effect on Ni migration. Indeed, with one oxygen vacancy, V_{O}1, the barrier is reduced to 0.8 eV, which corresponds to an increased hopping rate by a factor of 10¹³ at room temperature [≈exp(0.8 eV/kT)]. Higher vacancy concentrations (V_{O}1+V_{O}2) lead to an even smaller barrier of 0.5 eV, accompanying the final thermodynamic state energy stabilized by 0.2 eV below the initial state. Note that if only the oxygen vacancy V_{O}3 is formed, the effect on Ni migration is negligible. Contrary to V_{O}1 and V_{O}2, V_{O}3 is formed along the Ni migration pathway, which indicates that the vacancy effect on the migration barrier depends on the vacancy position: oxygen vacancies promote Ni diffusion along the opposite directions. This observation is similar to Qian's report on Li-rich layered oxides.^{[30]} Clearly, the formation of oxygen vacancies triggers Ni migration leading to the layered-spinel-rocksalt phase transitions.

2.3. Kinetics of Oxygen Evolution These modeling results on decreased bulk oxygen reduction (leading to facile oxygen evolution) and the oxygen vacancy-triggered Ni migration (leading to phase changes) seem to imply that bulk LiNiO₂ will be inevitably destabilized when charged over 200 mAh g⁻¹, due to bulk phase instability, and that only bulk alloy strategy (as empirically found for NCM and NCA cathodes) may alleviate the degradation problem. However, such conclusion is premature as the kinetics of oxygen vacancy formation is not examined, yet. As we discuss now, kinetic study on oxygen diffusion leads us to reach the opposite conclusion. Oxygen vacancy formation within the bulk oxide phase requires a kinetic process involving the migration of oxygen atoms through the Li layer to the oxide surface. To investigate the kinetics of oxygen vacancy formation, we have applied climbing image-nudged elastic band method (CI-NEB) and estimated the related oxygen migration barrier. We first modeled a single oxygen atom located in the Li layer with a nearby oxygen vacancy, and this structure is found to be thermodynamically unstable leading to a recombination of the O atom and oxygen vacancy. However, the formation of an oxygen dimer in Li layer (along with two oxygen vacancies) can be stable with formation energy of only 0.4 eV. As shown in FIG. 13a, the optimized oxygen dimer in the Li layer has a bond length of 1.27 Å, very close to the bond length of O₂ in the gas phase indicating that effectively an oxygen molecule is formed in Li layer. As shown in FIG. 20 (Supporting Information), with the formation of O₂ dimer, Bader charge analysis indicates electron transfer from these oxygen atoms to four neighboring Ni atoms, reducing the charge states of Ni by about 0.11 e⁻. Even though the formation energy is relatively low consistent with the vacancy formation energy in FIG. 10a, the kinetic barrier for this oxygen dimer formation is as high as 2.4 eV. Furthermore, oxygen dimers in Li layer are not mobile even if they are occasionally formed. FIG. 21 (Supporting Information) shows the trajectories of the diffusion of such O₂ dimer at 800 K for 10 ps, as obtained from ab initio molecular dynamics (AIMD). The trajectory of the O₂ dimer is always localized around the original site, and no evidence of oxygen diffusion into the neighboring sites in Li layer is observed. Note that this phenomenon is quite different from Li-rich layered oxides, in which the oxygen dimerization and migration are found with both thermodynamic stability and a relatively low kinetic barrier. The oxygen dimer formation energy in Li₂MnO₃ was calculated to be only 0.04 eV,^{[31]} and the corresponding oxygen migration barriers were estimated to be 0.6-0.9 eV, depending on the Li concentration and diffusion pathway.^{[24,32]} More recently, an AIMD study estimated the barrier to be as low as 0.35 eV for the Li₂MnO₃—LiCoO₂ composite.^{[33]} The different oxygen behavior between Li-rich compound and Ni-rich compound might be closely related with the appearance of Li ions in transition metal layer of Li-rich compounds. First of all, replacement of a transition metal atom with Li atom will weaken the bonding strength toward oxygen atom. Moreover, Li atoms locating at transition metal layer have been reported to have similar extracting voltage and migration barrier than those in Li layer.^{[31]} Therefore, once they diffuse out of transition metal layer during charging process, the bonding with oxygen is further weakened. In addition, appearance of empty atomic space in transition metal layer indicates larger space for oxygen atoms to migrate. This would open more possibilities for oxygen dimerization and migration in Li-rich compound.^{[32]} Therefore, Li-rich layered oxides would experience bulk phase transition, which accounts for one of the biggest challenges in bulk cathode material stabilization for their practical applications. Different from Li-rich oxides, our results indicate that oxygen evolution in LiNiO₂-based bulk oxides is actually kinetically prohibited, although bulk oxygen evolution and phase transition are possible from a thermodynamic standpoint. Nevertheless, there have been many experimental reports about oxygen loss during cycling and heating of LiNiO₂,^{[13,34-36]} leading to the question: if oxygen evolution is kinetically prohibited, where does the observed oxygen gas come from?

2.4. Surface Oxygen Evolution and Phase Transition A conceptual consensus on kinetics for layered oxides is that ion migration barrier is closely related to the available space along the diffusion path: a larger space gives rise to smaller migration barriers, and vice versa.^{[37,38]} This observation indicates a possibility that oxygen evolution can happen on crystal regions with more open space with reduced migration barrier for the oxygen atom or dimer. Specifically, in the cathode oxide powder systems, surface and grain boundary regions can provide such open space for ion migration. In order to investigate the effect of the available space on oxygen migration, we have compared atomic kinetics in the oxide bulk and surface regions. AIMD was used to heat up the Li_{0.25}NiO₂ bulk phase and Li_{0.28}NiO₂ (104) surface to 800 K, as a means to accelerate the kinetic processes. The (104) facet is the predominant surface for as-synthesized LiNiO₂ at high temperature in O-rich environment, and thus it has been adopted as our surface model.^{[39]} This confirmed by an energy comparison for different surface facets as a function of the oxygen chemical potential is also given in FIG. 22 (Supporting Information), as well as in our recently published work.^{[40]} As shown in FIG. 14a, only Li diffusions are observed in the bulk phase during 5 ps of simulation time, and there is no evidence for oxygen migration. This finding is consistent with the small barrier for Li migration (0.33 eV)^{[37,38]} and the high formation kinetic barrier of the oxygen dimer (2.4 eV). However, FIG. 14b indicates that the oxygen migration to Li layer emerges at only 1 ps simulation of the (104) surface. This is more clearly illustrated in FIG. 14c, in which there are two oxygen atoms migrating out of original sites to the neighboring Li layer and form two O—O dimers with nearby oxygen atoms. The O₂ dimers have bond lengths of 1.33 and 1.25 Å, respectively, very close to the O—O dimer of 1.27 Å formed in bulk phase (FIG. 14a). The surface oxygen vacancy formation is also followed by Ni migration into the Li layer. As discussed previously, Ni migration could form the nucleus for the layer-spinel-rocksalt phase transitions,^{[24]} and thus surface oxygen evolution triggering Ni migration could also promote the surface phase transitions. Note that our surface model is based on a simplified vacuum/surface system, without including realistic surface reactions due to the presence of LiPF₆ salt and ethylene carbonate/ethylmethyl carbonate/dimethyl carbonate (EC/EMC/DMC) solvents in the electrolyte. Nevertheless, these AIMD results indeed reveal the different oxygen kinetic activities between the bulk and the surface: surface oxygen is much more favorable to migrate and evolve into O₂ gas upon delithiation. In fact, according to the theoretical results by Yang group, nucleophilic attack and dissociation of an EC molecule could further promote the surface oxygen evolution and solid electrolyte interphase (SEI) layer formation.^{[16,17]} Electronic structure analysis has assigned the underlying mechanism to the penetration of carbonate molecular HOMO to the O 2p band, which integrates with transition metal 3d bands after delithiation and leads to electron transfer between carbonate molecular and electrode materials, thus SEI layer formation.^{[16,18]} Their finding is consistent with our explanations based on FIGS. 10 and 11, and the results are further supported by our Bader charge analysis on surface oxygen. The average Bader charge of oxygen atoms on (104) surface is calculated to be only −0.75 e⁻, while that in the bulk is −0.85 e⁻. Therefore, reduction of surface oxygen is further decreased compared with bulk oxygen, and consequently less stable. Together with the available open spaces for oxygen migration and the possibility to react with electrolyte salts, the surface region of LiNiO₂-based oxides would be exposed to vigorous driving forces for oxygen evolution, phase transitions, and other reactions.

2.5. Experimental Study on Bulk versus Surface Behavior To validate the main findings of our computational analysis (i.e., oxygen evolution and degradation of LiNiO₂ happen only on the surface regions, but not within bulk phase), experimental synthesis, cycling test, and characterization of LiNiO₂ have also been carried out. LiNiO₂ powders were synthesized using conventional sol-gel method as described in the Experimental Section. Scanning electron microscopy (SEM) characterization of the as-synthesized powders is presented in FIGS. 15a-c and FIG. 23 (Supporting Information). The primary particles have sizes of 1-3 μm, and are aggregated to form secondary particles of amorphous shapes with a wide size distribution over 10-50 μm. By cleaving a secondary particle with focused ion beam (FIB), the porous internal structures are observed as shown in FIG. 15c. High porosity indicates high surface/volume ratio of the sol-gel synthesized LiNiO₂ powders. The X-ray diffraction (XRD) characterization in FIG. 15d confirms the layered crystalline structure, with all the identity peaks present and a clear splitting of the (006)/(012) and (018)/(110) peaks. The high (003)/(104) ratio of 1.66 indicates a good electrochemical activity with reduced amount of Li/Ni mixing defects.^{[11,41]} The electrochemical performance was tested by assembling electrode materials into LiNiO₂Li half cells. FIG. 15e gives the charging/discharging profile at 0.1 C current rate with a cutoff voltage of 4.3 V. The initial charging capacity can approach 229 mAh g⁻¹, while the initial discharge capacity is reduced to 187 mAh g⁻¹, giving rise to an initial Coulombic efficiency of 82%. The large initial capacity loss originates from many factors: SEI layer formation due to large surface/volume ratio of sol-gel synthesized LiNiO₂,^{[42,43]} surface phase transition,^{[10]} as well as Li-depletion regions due to extra Ni-defects which are difficult to be completely eliminated during high-temperature calcination.^{[44]} A recent work on the optimization of the powder morphology and extra Ni-defect concentration through advanced coprecipitation methods has effectively showed improved initial Coulombic efficiency^{[45,46]} indicating a room for further optimization.

After the initial charging/discharging at low current rate, the capacity retention of LiNiO₂ was tested at higher rate of 0.5 C for 100 cycles. As plotted in FIG. 16a, the initial discharge capacity at 0.5 C shows a smaller value of 150 mAh g⁻¹, and degrades fast down to 20 mAh g⁻¹ at the 100th cycle, giving rise to the capacity retention of only 13%. These performances are close to previous reports for LiNiO₂ powders obtained by similar synthesis methods.^{[41,47,12,48]} FIG. 16b illustrates the voltage-capacity profiles for the selected cycles. Apart from the capacity degradation, the overpotential of the battery increases as well: after 100 cycles of charging/discharging, the average charging voltage increases from ≈4.0 to ≈4.2 V, while average discharging voltage decreases from ≈3.6 to ≈3.4 V, respectively. Such increment of the overpotential indicates intensified polarization arising from increased internal resistance and newly formed phases, for which a higher energy is required to drive electrons and ions out of (into) the cathode during charging (discharging) process.^{[49-51]} After the 100th cycle, the coin cell was disassembled, and the electrode materials are collected to perform XRD characterization. The XRD profile, plotted in FIG. 16c, reveals that the oxide powders have kept the layered structure, with the same identity peaks as pristine LiNiO₂ before cycling, without any evidence of spinel or rocksalt phase formation. Considering that XRD is giving information about crystal structures of bulk materials, this finding of negligible change in XRD peaks means that no bulk phase transition has occurred: supporting our simulation results that oxygen evolution is kinetically forbidden in bulk by high kinetic barriers.

In order to compare the oxygen evolution (measured by oxygen loss) from surface and bulk regions, Ni and O relative concentrations (with summation of Ni and O concentrations set to 100%) have been obtained from energy dispersive X-ray spectrometer (EDS) and X-ray photoelectron spectroscopy (XPS). Since EDS collects X-ray emitted from powders, it provides materials information at a depth of several micro meters below the surface, thus reflecting the atomic concentration of the bulk phase. Different from EDS, XPS collects electrons emitted from materials, thus only information from surface atomic layers, normally several nanometers deep, can be obtained. Therefore, by comparing EDS and XPS results, the chemical composition differences between the bulk and surface regions can be determined. The original data for both measurements are included in Tables S1 and S2, FIG. 24 (Supporting Information). The relative Ni and O concentrations derived from EDS are plotted in FIG. 16d, showing that Ni and O concentrations in bulk do not change much after cycling. The O/Ni ratio varies from 2.4 to 2.8, close to the value of stoichiometric LiNiO₂, considering that the error in EDS elemental analysis can be of 3-8%. Therefore, EDS confirms that no significant oxygen evolution (loss) accompanying phase transitions have occurred in the bulk region. The XPS surface O/Ni ratio change is also included in FIG. 16d. From XPS, the O/Ni ratio for pristine LiNiO₂ is 3.6, much larger than the 2.4 value deduced from EDS. We expect that surface Li₂CO₃ formation from carbonate reaction with LiNiO₂ or residual Li salt reaction with air contributes to the higher concentration of surface oxygen.^{[48]} This is supported by the XPS analysis of the O 1S peak in FIG. 25 (Supporting Information), which matches with literature reports.^{[52]} However, the surface O/Ni ratio after cycling is reduced to 1.1. This value clearly indicates surface oxygen loss, and is close to the stoichiometry of rocksalt NiO phase or mixture of spinel LiNi₂O₄ and NiO. This finding is also consistent with other experimental results.^{[13,36]} For example, Hwang et al. combined TEM and electron energy loss spectroscopy (EELS) methods and showed that charged NCA particle edge has much lower peak intensity for oxygen in EEL spectra, an indication of the formation of a rocksalt phase (Fm 3̅m).^{[10]} A heating study on overcharged NCA and NCM111 with high-resolution TEM also showed that phase transition starts from the surface phase nucleation and propagates into the bulk phase upon increasing temperature.^{[6,53]} Therefore, these combined EDS/XPS analyses support the theoretical finding that phase transition happens only on surface regions at which the oxygen evolution is facilitated by decreased oxygen reduction and the enhanced migration kinetics.

2.6. Degradation Mechanism and Stabilization Principle Based on these theoretical and experimental findings, we can summarize the thermodynamics and kinetics of degradation during oxygen evolution of LiNiO₂-based cathode materials, and provide an answer to the questions raised in the Introduction. Due to the increased covalent nature of Ni—O bonding, oxygen is less reduced during delithiation, and the resulting weak bonding destabilizes oxygen atoms, as demonstrated by the lower formation energy of oxygen vacancies. This facile oxygen vacancy formation in bulk provides a strong thermodynamic driving force for oxygen evolution. However, due to the high oxygen diffusion and dimer formation kinetic barriers in bulk phase, the oxygen evolution is kinetically prohibited. However, reduction of oxygen atoms can be further decreased in surface regions with open space, and the open space allows the accelerated kinetic process of oxygen evolution. Moreover, salt and carbonate molecular species in the liquid electrolyte can react with the exposed surface regions, and such reducing environment further increases the oxygen evolution rate and subsequent phase transformations. Once surface phase transition forms spinel and rocksalt phases, the rapid diffusion of Li ion within Li layered is hindered at surface, leading to increased overpotential and rapid capacity degradation, even though majority of bulk LiNiO₂ phase remains intact.

In spite of many reports on degradation issues of LiNiO₂ cathode in LIB, these findings actually indicate that LiNiO₂-based layered cathode materials are very promising candidate for 200 mAh g⁻¹ or higher charge capacity, benefiting from their bulk kinetic stability. Since oxygen evolution and capacity degradation are clearly identified to be limited in surface regions of LiNiO₂, a strategy of developing effective surface protection coatings as oxygen blocking layers would be crucial to achieve stabilized LiNiO₂. Promising surface coating materials should have strong oxygen binding strength and, also have both electronic and ionic conductivities to allow efficient charge carrier transport. Our findings also provide an underlying rationale why Ni-rich cathode materials with a full concentration gradient design (i.e., high Ni at core and reduced Ni on surface) are more stable than bulk doped oxides in thermal and cycling stability performance.^{[54]} Moreover, because the molecular species of the electrolyte react with less reduced surface oxygen leading to accelerated degradation, we expect that the design of effective surface coating will replace the LiNiO₂ surface/electrolyte interface by more stable surface coating/electrolyte interface. Based on such coating strategy, it would be possible to achieve even ≈90% of the theoretical capacity of LiNiO₂ (≈250 mAh g⁻¹).

3. Experimental Section DFT Calculations: The calculations in this work were performed using DFT method with plane wave basis sets and projector-augmented wave (PAW) pseudopotentials, as implemented in VASP code.^{[55-57]} The generalized gradient approximation with Perdew-Burke-Ernzerhof (GGA-PBE) functional was used to describe exchange and correlation interactions.^{[58]} A plane wave cutoff energy of 500 eV and Gamma centered k-point mesh of 3×3×3 was used for all calculations, with an energy convergence of 1 meV per unit cell. The atomic structure optimization was performed with allowing relaxation of both shape and volume of supercells, until the total energy was converged to 10⁻⁴ eV and the forces on every atom were less than 0.05 eV Å⁻¹. The self-consistent calculations adopted the tetrahedron method with Blöchl corrections,^{[59]} and the energy convergence criteria was set to be 10⁻⁵ eV. Spin-polarization was considered for all calculations. To account for electron localization in transition metal oxides, an effective on-site Hubbard Ueff correction on the 3d electrons was employed for transition metals.^{[60]} The U_{eff} values are 3.0, 3.5, 5.0, 3.0, 4.0, 6.4, and 4.0 eV for V, Cr, Mn, Fe, Co, Ni, and Cu, respectively. These values were adopted from previous theoretical works on GGA+U study of lithiated transition metal oxides.^{[61,62]} Structural configurations in this work were plotted using the VESTA software.^{[63]}

To avoid imaginary defect interactions due to periodic boundary conditions in DFT calculations, a large supercell model of LiNiO₂ composed of 32 unit cells (Li₃₂Ni₃₂O₆₄, for a total of 128 atoms) was adopted to obtain the oxygen vacancy formation energy. The oxygen vacancy formation energy was calculated based on the following formula

$$\begin{matrix}Δ {G}_{v}^{0} = {G}^{0} ( T , {Li}_{x} {Ni}_{16} {O}_{31} ) + \frac{1}{2} {G}^{0} ( T , {O}_{2} ) - {G}^{0} ( T , {Li}_{x} {Ni}_{16} {O}_{32} ) \\ ≅ {E}^{DFT} ( {Li}_{x} {Ni}_{16} {O}_{31} ) + \frac{1}{2} {G}^{0} ( T , {O}_{2} ) - {E}^{DFT} ( {Li}_{x} {Ni}_{16} {O}_{32} ) .\end{matrix} \qquad ( 1 )$$

G⁰ is the Gibbs free energy. For solid phases the entropy and volume terms can be disregarded, thus the formation energy is given as E^{DFT}, which represents the DFT total energy at 0 K. However, since chemical potential of gaseous O₂ depends on temperature, the Gibbs free energy of gaseous O₂ in the JANAF thermochemical tables was used to estimate the temperature effect on oxygen vacancy formation.^{[44,64]} These data are given in FIG. 26 (Supporting Information). For oxygen vacancy formation energy calculation, the chemical potential of oxygen at room temperature which is 8.99 eV/molecule was applied. The dependence of ΔGᵥ⁰ on oxygen partial pressure P at temperature T is given as

$$Δ {G}_{v}^{0} ( P , T ) = Δ {G}_{v}^{0} ( T ) + \frac{1}{2} {k}_{B} T ln ( \frac{p}{{p}^{0}} ) , \qquad ( 2 )$$

in which p⁰ is the standard oxygen pressure (0.2 atm), k_{B} is Boltzmann constant. Under thermal equilibrium, the concentration of oxygen vacancy at temperature T and oxygen partial pressure P can be derived as

$${C}_{v} ( P , T ) = {Ne}^{- \frac{Δ {C}_{v}^{0} ( P , T )}{{k}_{B} T}} , \qquad ( 3 )$$

where N is the total number of oxygen atom site in the supercell.

AIMD calculations were applied to investigate and track atomic diffusions at elevated temperatures. The Brillouin zone sampling was performed with a k-mesh of 1×1×1 at the Γ point. AIMD calculations were conducted using the Nosé thermostat with a time step of 2 fs in a NVT ensemble with constant volume.^{[65]} The ion migration barriers in this work were obtained using the CI-NEB, for which the minimum energy path (MEP) from the initial to the final state can be obtained.^{[66]} The reaction path was divided into a set of images “connected with a spring.” By keeping the initial and final states frozen, the image structures were optimized according to the constraint of the “elastic band.” When the components of the forces perpendicular to the elastic band vanish, the MEP and corresponding transition states and migration barriers can be determined.^{[66]}

Synthesis: LiNiO₂ was synthesized using conventional sol-gel method.^{[41]} Lithium nitrate (LiNO₃, 99.99%, Sigma-Aldrich) and nickel nitrate hexahydrate (Ni(NO₃)₂.6H₂O, 99.99%, Sigma-Aldrich) were used as the precursors with a mole ratio of 1.05:1. Extra Li precursor was used to compensate Li lost during high-temperature calcination and achieve better stoichiometry. The precursors were dissolved in deionized (DI) water, afterward a chelating agent, citric acid (C₂H₅O₇, >99.5%, Sigma-Aldrich), was also added into the aqueous solution to facilitate the formation of homogenous cation networks. The solutions were heated up to 80° C. and stirred by a magnetic bar at 400 rpm until a green gel was formed. The gel was then transferred to a crucible, and calcinated in a box furnace at 600° C. for 5 h to remove the organic substances. After this step, the powders were transferred to the tube furnace for final calcination at 790° C. for 13 h under O₂ flow. To obtain the best stoichiometry, a slow ramping up and down rate of 1° C. min⁻¹ was applied.

Characterization: Phase identification was carried out by XRD analysis through Rigaku Ultima III diffractometer with Cu Kα radiation. The scanning rate was 2° min⁻¹ and the scanning range of diffraction angle (2θ) was 15°-90°. Surface chemistry analysis was performed with XPS. XPS data were collected using a monochromated Al Kα X-ray source (1486.7 eV). The working pressure of the chamber was lower than 6.6×10⁻⁷ Pa. All reported binding energy values were calibrated to the C is peak at 284.8 eV. The morphology and microstructures of LiNiO₂ secondary particles were characterized by a dual beam FIB workstation (FEI Nova 200, USA) equipped with EDS. (The samples were first milled to cross sections under the ion beam and then observed under the electron beam.)

Electrochemistry: CR2032 coin cells were assembled in an argon-filled glove box, with O₂ and H₂O concentration being controlled to be in the ppm level. The positive electrode is composed of 90 wt. % active oxides, 5 wt. % carbon black and 5 wt. % polyvinylidene difluoride (PVDF) binder, and mixed in an agate mortar. The mixed powders are dissolved in N-Methyl-2-pyrrolidone (NMP) solvent and casted onto Al foil. The casted electrode was then dried in the vacuum oven overnight at 100° C. The battery cell is prepared in half-cell type with Li metal as the negative electrode. The organic electrolyte, 1.0 M LiPF₆ in EC/DMC=50/50 (v/v), was obtained from Sigma-Aldrich. Electrochemistry cycling tests were performed using Arbin's Laboratory Battery Testing (LBT) system. To characterize LiNiO₂ powders after electrochemical testing, the coin cell is disassembled after 100^{th} cycles. The mixed electrode powders are scratched off Al foil, collected, washed with Isopropyl alcohol (IPA) solution, and dried in a vacuum oven.

### REFERENCES

[1] K. M. Shaju, G. V. S. Rao, B. V. R. Chowdari, Electrochim. Acta 2002, 48, 145.
[2] M. S. Whittingham, Chem. Rev. 2004, 104, 4271.
[3] H.-J. Noh, S. Youn, C. S. Yoon, Y.-K. Sun, J. Power Sources 2013, 233, 121.
[4] S.-K. Jung, H. Gwon, J. Hong, K.-Y. Park, D.-H. Seo, H. Kim, J. Hyun, W. Yang, K. Kang, Adv. Energy Mater. 2014, 4, 1300787.
[5] S. Hwang, S. M. Kim, S. M. Bak, S. Y. Kim, B. W. Cho, K. Y. Chung, J. Y. Lee, E. A. Stach, W. Chang, Chem. Mater. 2015, 27, 3927.
[6] K.-W. Nam, S.-M. Bak, E. Hu, X. Yu, Y. Zhou, X. Wang, L. Wu, Y. Zhu, K.-Y. Chung, X.-Q. Yang, Adv. Funct. Mater. 2013, 23, 1047.
[7] H. Arai, S. Okada, Y. Sakurai, J. Yamaki, Solid State Ionics 1998, 109, 295.[8] M. Guilmard, L. Croguennec, D. Denux, C. Delmas, Chem. Mater. 2003, 15, 4476.
[9] S. Hwang, S. M. Kim, S. M. Bak, K. Y. Chung, W. Chang, Chem. Mater. 2015, 27, 6044.
[10] S. Hwang, W. Chang, S. M. Kim, D. Su, D. H. Kim, J. Y. Lee, K. Y. Chung, E. A. Stach, Chem. Mater. 2014, 26, 1084.
[11] P. Kalyani, N. Kalaiselvi, Sci. Technol. Adv. Mater. 2005, 6, 689.
[12] J. Cho, T.-J. Kim, Y. J. Kim, B. Park, Electrochem. Solid-State Lett. 2001, 4, A159.
[13] W. Liu, P. Oh, X. Liu, M.-J. Lee, W. Cho, S. Chae, Y. Kim, J. Cho, Angew. Chem., Int. Ed. 2015, 54, 4440.
[14] R. M. D., H. Sunny, S. Mahsa, F. Chengcheng, L. Haodong, V. Julija, Z. Minghao, W. M. Stanley, M. Y. Shirley, V. der V. Anton, Adv. Energy Mater. 2017, 7, 1602888.
[15] S.-M. Bak, K.-W. Nam, W. Chang, X. Yu, E. Hu, S. Hwang, E. A. Stach, K.-B. Kim, K. Y. Chung, X.-Q. Yang, Chem. Mater. 2013, 25, 337.
[16] M. Gauthier, T. J. Carney, A. Grimaud, L. Giordano, N. Pour, H.-H. Chang, D. P. Fenning, S. F. Lux, O. Paschos, C. Bauer, F. Maglia, S. Lupart, P. Lamp, Y. Shao-Horn, J. Phys. Chem. Lett. 2015, 6, 4653.
[17] L. Giordano, P. Karayaylali, Y. Yu, Y. Katayama, F. Maglia, S. Lux, Y. Shao-Horn, J. Phys. Chem. Lett. 2017, 8, 3881.
[18] M. K. Aydinol, A. F. Kohan, G. Ceder, K. Cho, J. Joannopoulos, Phys. Rev. B 1997, 56, 1354.
[19] R. C. Longo, F. T. Kong, S. Kc, M. S. Park, J. Yoon, D.-H. Yeon, J.-H. Park, S.-G. Doo, K. Cho, Phys. Chem. Chem. Phys. 2014, 16, 11233.
[20] K. Shimoda, M. Oishi, T. Matsunaga, M. Murakami, K. Yamanaka, H. Arai, Y. Ukyo, Y. Uchimoto, T. Ohta, E. Matsubara, Z. Ogumi, J. Mater. Chem. A 2017, 5, 6695.
[21] K.-K. Lee, W.-S. Yoon, K.-B. Kim, K.-Y. Lee, S.-T. Hong, J. Power Sources 2001, 97, 321.
[22] P. Xiao, Z. Q. Deng, A. Manthiram, G. Henkelman, J. Phys. Chem. C 2012, 116, 23201.
[23] N. Yabuuchi, M. Nakayama, M. Takeuchi, S. Komaba, Y. Hashimoto, T. Mukai, H. Shiiba, K. Sato, Y. Kobayashi, A. Nakao, M. Yonemura, K. Yamanaka, K. Mitsuhara, T. Ohta, Nat. Commun. 2016, 7, 13814.
[24] E. Lee, K. Persson, Adv. Energy Mater. 2014, 4, 1400498.
[25] D.-H. Seo, J. Lee, A. Urban, R. Malik, S. Kang, G. Ceder, Nat. Chem. 2016, 8, 692.
[26] K. Duho, C. Maenghyo, C. Kyeongjae, Adv. Mater. 2017, 29, 1701788.
[27] H. Arai, S. Okada, Y. Sakurai, J. Yamaki, Solid State Ionics 1998, 106, 45.
[28] R. E. Ruther, A. S. Pandian, P. Yan, J. N. Weker, C. Wang, J. Nanda, Chem. Mater. 2017, 29, 2997.
[29] C. T. Love, W. Dmowski, M. D. Johannes, K. E. Swider-Lyons, J. Solid State Chem. 2011, 184, 2412.
[30] D. Qian, B. Xu, M. Chi, Y. S. Meng, Phys. Chem. Chem. Phys. 2014, 16, 14665.
[31] R. Xiao, H. Li, L. Chen, Chem. Mater. 2012, 24, 4242.
[32] H. Chen, M. S. Islam, Chem. Mater. 2016, 28, 6656.
[33] R. Benedek, H. Iddir, J. Phys. Chem. C 2017, 121, 6492.
[34] K.-W. Nam, S.-M. Bak, E. Hu, X. Yu, Y. Zhou, X. Wang, L. Wu, Y. Zhu, K.-Y. Chung, X.-Q. Yang, Adv. Funct. Mater. 2013, 23, 1047.
[35] W.-S. Yoon, K. Y. Chung, M. Balasubramanian, J. Hanson, J. McBreen, X.-Q. Yang, J. Power Sources 2006, 163, 219.
[36] W. Li, B. Song, A. Manthiram, Chem. Soc. Rev. 2017, 25, 4890.
[37] K. Kang, Y. S. Meng, J. Brdger, C. P. Grey, G. Ceder, Science 2006, 311, 977.
[38] F. Kong, C. Liang, R. C. Longo, D.-H. Yeon, Y. Zheng, J.-H. Park, S.-G. Doo, K. Cho, Chem. Mater. 2016, 28, 6942.
[39] E. Cho, S.-W. Seo, K. Min, ACS Appl. Mater. Interfaces 2017, 9, 33257.
[40] C. Liang, R. C. Longo, F. Kong, C. Zhang, Y. Nie, Y. Zheng, K. Cho, ACS AppL. Mater. Interfaces 2018, 10, 6673.
[41] M. Y. Song, R. Lee, J. Power Sources 2002, 111, 97.
[42] E. Peled, S. Menkin, J. Electrochem. Soc. 2017, 164, A1703.
[43] S.-T. Myung, F. Maglia, K.-J. Park, C. S. Yoon, P. Lamp, S.-J. Kim, Y.-K. Sun, ACS Energy Lett. 2017, 2, 196.
[44] F. Kong, C. Liang, R. C. Longo, Y. Zheng, K. Cho, J. Power Sources 2018, 378, 750.
[45] C. S. Yoon, M. H. Choi, B.-B. Lim, E.-J. Lee, Y.-K. Sun, J. Electrochem. Soc. 2015, 162, A2483.
[46] L. Wangda, L. Xiaoming, C. Hugo, S. Patrick, D. Andrei, C. Miaofang, M. Arumugam, Adv. Energy Mater. 2018, 8, 1703154.
[47] Y. S. Lee, Y. K. Sun, K. S. Nahm, Solid State Ionics 1999, 118, 159. [48] J. Kim, Y. Hong, K. S. Ryu, M. G. Kim, J. Cho, Electrochem. Solid-State Lett. 2006, 9, A19.
[49] C. Liu, Z. G. Neale, G. Cao, Mater. Today 2016, 19, 109.
[50] M. Tang, W. C. Carter, Y.-M. Chiang, Annu. Rev. Mater. Res. 2010, 40, 501.
[51] J. B. Goodenough, K.-S. Park, J. Am. Chem. Soc. 2013, 135, 1167. [52] A. N. Mansour, Surf. Sci. Spectra 1994, 3, 279.
[53] L. Wu, K.-W. Nam, X. Wang, Y. Zhou, J.-C. Zheng, X.-Q. Yang, Y. Zhu, Chem. Mater. 2011, 23, 3953.
[54] Y.-K. Sun, S.-T. Myung, B.-C. Park, J. Prakash, I. Belharouak, K. Amine, Nat. Mater. 2009, 8, 320.
[55] G. Kresse, J. Hafner, Phys. Rev. B 1993, 47, 558.
[56] G. Kresse, J. Furthmuller, Phys. Rev. B 1996, 54, 11169. [57] G. Kresse, D. Joubert, Phys. Rev. B 1999, 59, 1758.
[58] J. P. Perdew, K. Burke, M. Ernzerhof, Phys. Rev. Lett. 1996, 77, 3865.
[59] P. E. Blöchl, O. Jepsen, O. K. Andersen, Phys. Rev. B 1994, 49, 16223.
[60] S. L. Dudarev, G. A. Botton, S. Y. Savrasov, C. J. Humphreys, A. P. Sutton, Phys. Rev. B 1998, 57, 1505.
[61] C. Liang, F. Kong, R. Longo, C. Zhang, Y. Nie, Y. Zheng, K. Cho, J. Mater. Chem. A 2017, 5, 25303.
[62] F. Kong, R. C. Longo, M.-S. Park, J. Yoon, D.-H. Yeon, J.-H. Park, W.-H. Wang, S. KC, S.-G. Doo, K. Cho, J. Mater. Chem. A 2015, 3, 8489.
[63] K. Momma, F. Izumi, J. Appl. Crystallogr. 2011, 44, 1272.
[64] M. W. Chase, J. Phys. Chem. Ref. Data 1996, 25, 551.
[65] S. Nos6, J. Chem. Phys. 1984, 81, 511.
[66] G. Henkelman, H. J. B. P. Uberuaga, J. Chem. Phys. 2000, 113, 9901.

Supporting Information

Cluster Expansion Method.

Cluster expansion method is used to define intermediate stable states during delithiation of LiNiO₂. We determined that the ordered phases with Li concentration at 0.25, 0.4, 0.5 and 0.75 are intermediate stable (See FIG. 17).

Cluster expansion method as implemented in the Alloy-Theoretic Automated Toolkit (ATAT) was used.^{[67]} The phases with different Li-vacancy orderings predicted from cluster expansion were expanded into a polynomial as a function of discrete occupation variables σi:^{[68]}

E(σ)=J₀+ΣᵢJᵢσᵢ+Σ_{i,j}Jᵢⱼσᵢσⱼ+Σ_{i,j,k}Jᵢⱼₖσᵢσⱼσₖ+ . . . , (S1)

in which i, j, k, . . . correspond to a collection of interstitial sites that form pair, triplet, clusters, etc. The multiple value of σᵢ, σₖ, σⱼ, . . . is the correlation function (Πσ) for the corresponding configuration. Coefficients J₀, J₁, Jᵢⱼ are the effective cluster interactions (ECI).^{[67]} The cross-validation (CV) score (0.02 eV/f.u.) is adopted to select an optimal set of clusters:

(CV)²=n⁻¹Σᵢ₌₁ⁿ[wᵢ(Eᵢ(σ)−\vec{Eₗ}(σ))]², (S2)

in which E(σ) is the energy predicted by cluster expansion, \vec{Eₗ} (σ) is the energy calculated by first principles, wᵢ remarks the weight of a specific configuration. In this work, six pairs, four triplets, and one quadruplet cluster were included for all structures to fit these ECI coefficients. Totally 62 configurations were generated.

FIG. 17. (a) Formation energies calculated from the 62 different configurations during delithiation of LiNiO₂. And the configurations of intermediate stable LiₓNiO₂ with (b) x=0.75, (c) x=0.5, (d) x=0.4 and (e) x=0.25. (Color code: Green for Li—O octahedron, Grey for Ni—O octahedron, red for O atom.).

FIG. 18. Concentration of oxygen vacancy at thermal equilibrium in deep-charged LiNiO₂ (Li_{0.25}NiO₂) under different oxygen partial pressures as a function of temperature.

FIG. 19. Illustration of Ni reduction due to oxygen vacancy formation. The reduced Ni is highlighted by blue color. Green, grey and red balls represent Li, Ni and O atoms.

FIG. 20. Illustration of Ni reduction due to oxygen dimer formation. The reduced Ni is highlighted by blue color. Green, grey and red balls represent Li, Ni and O atoms.

FIG. 21. Trajectories of O₂ dimer in Li layer at 800 K for 10 ps, obtained from ab initio molecular dynamics (AIMD). Green, grey and red spheres represent Li, Ni and O atoms, respectively.

FIG. 22. Surface energy of LiNiO₂ as a function of oxygen chemical potential. The sandwich model with two symmetric surfaces on both sides is used for surface energy calculation, and the vacuum layer is set to be 15 Å to avoid layer-layer interaction. Surface energy is defined as

$$= \frac{{E}_{tot} - {E}_{bulk} + {\sum }_{i} {n}_{i} {μ}_{i}}{2 A} ,$$

in which Eₜₒₜ and E_{bulk} are the total energies of surface and bulk phases, respectively. Nonstoichiometric surfaces were calculated by considering the chemical potential μᵢ of the elements in excess or shortage of nᵢ. This figure indicates O-rich environment would induce the predominate (104) surfaces.

FIG. 23. SEM profile after-synthesized LiNiO₂ powders at different resolutions.

TABLE S1
The relative atomic concentrations of Ni and O derived from
XPS at different measuring spots. Concentration of Ni and
O are derived from Ni 2p3 and O 1 s peaks, respectively.
And the concentration is fitted using CasaXPS software.

| | | Spot | Spot | Spot | Spot | Spot | Spot |
|---|---|---|---|---|---|---|---|
| LiNiO₂ | Element | 1 | 2 | 3 | 4 | 5 | 6 |
| Before | Ni | 30.18 | 29.08 | 29.59 | 30.36 | 30.29 | 29.93 |
| Cycling | O | 69.82 | 70.92 | 70.41 | 69.64 | 69.71 | 70.07 |
| After 100 | Ni | 27.14 | 26.65 | 26.00 | 27.31 | 25.35 | 26.49 |
| Cycles | O | 72.86 | 73.35 | 74.00 | 72.69 | 74.65 | 73.51 |

TABLE S2
The relative atomic concentrations of Ni and O
derived from EDS at different measuring spots.

| | | Spot | Spot | Spot |
|---|---|---|---|---|
| LiNiO₂ | Element | 1 | 2 | 3 |
| Before | Ni | 23.63 | 20.22 | 20.92 |
| Cycling | O | 76.41 | 79.78 | 79.08 |
| After 100 | Ni | 47.82 | 41.32 | 53.89 |
| Cycles | O | 52.18 | 58.68 | 46.11 |

FIG. 24. XPS survey of elements in LiNiO₂ powders (a) before and (b) after cycling. Fluorine peak originates from LiPF₆ salt in electrolyte and PVDF polymer binder.

FIG. 25. XPS O 1s peak of pristine LiNiO₂. Fitting is finished through CasaXPS software and the peak has been allied to C is at 284.8 eV.

FIG. 26. Chemical potential of O₂ as a function of temperature.

FIG. 27. (a), (c) The SEM profile of LiNiO₂ powders before cycling. (b), (d) The SEM profile of LiNiO₂ powders after 100^{th} cycling.

FIG. 28. TEM characterization of LiNiO₂ particles after 100^{th} cycling with different resolutions. The figures show evidence of high density of intragranular cracks and their connections between intergranular cracks, highlighted with arrows.

### SUPPLEMENTARY REFERENCES

[1] A. van de Walle, Calphad 2009, 33, 266-278.
[2] J. M. Sanchez, F. Ducastelle, D. Gratias, Phys. A Stat. Mech. its Appl. 1984, 128, 334-350.

Those skilled in the art to which this application relates will appreciate that other and further additions, deletions, substitutions and modifications may be made to the described embodiments.

1. A cathode composition, comprising:
a core cathode body, the core cathode body composed of nickel oxide crystallite particles; and
a surface cathode coating layer contacting and at least partially surrounding an outer surface of the core cathode body, wherein the surface cathode coating layer includes a plurality of grains, adjacent ones of the grains separated by grain boundaries, and, each of the grains:
includes one or more of a transition metal or post-transition metal oxide or fluoride,
includes one or more of lanthanide row atoms having a concentration in a range from about 0.1 to 10 mol %,
has a thickness in a range from about 0.5 to 30 nm, and
has an amorphous, polycrystalline or composite amorphous/polycrystalline atomic structure.

2. The composition of claim 1, wherein the transition metal or post-transition metal oxide is one or more of TiO₂, ZnO, ZrO₂, HfO₂ or Al₂O₃.

3. The composition of claim 1, wherein the transition metal or post-transition metal fluoride is one or more of FeF₂, CuF₂, or AlF₃.

4. The composition of claim 1, wherein the lanthanide row atoms is one or more of La, Ce, Sm or Gd.

5. The composition of claim 1, wherein the at least partially surrounding surface cathode coating layer contacts about 80 percent or more of the outer surface of the core cathode body.

6. The composition of claim 1, wherein the nickel oxide of the core cathode body includes up to 30 mol % of a non-nickel first row transition metal or a post-transition metal.

7. The composition of claim 1,
wherein the cathode composition forms part of a cathode electrode structure in a lithium ion battery assembly and the cathode electrode structure forms a plurality of layers where the layers are separated from each other by an electrolyte medium including lithium ions.

8. The composition of claim 7, wherein the electrolyte medium includes the lithium ions as a LiPF₆ organic electrolyte.

9. The composition of claim 8, wherein, the cathode composition, in the presence of the electrolyte medium including the lithium ions and in a fully charged state, the core cathode body has a chemical formula of Li₁₋ₓNiO₂, where x≥0.7.

10. The composition of claim 8, wherein, a mole ratio of Ni:O at an outer surface of the core cathode body, after at least 100 charge-discharge cycles of the cathode electrode structure, is within 30 percent of the mole ratio of Ni:O at the outer surface of the core cathode body before the charge-discharge cycles.

11. The composition of claim 7, wherein the battery assembly further includes an anode electrode structure and a separation barrier between the cathode electrode structure and the anode electrode structure.

12. The composition of claim 7, wherein the battery assembly is configured as an electrical power supply for a vehicle.

13. A method of manufacture, comprising:
preparing a cathode composition, including:
forming a core cathode body, the core cathode body composed of nickel oxide crystallite particles; and
forming by atomic layer deposition (ALD), a surface cathode coating layer contacting and at least partially surrounding an outer surface of the core cathode body wherein, the surface cathode coating layer includes a plurality of grains, adjacent ones of the grains separated by grain boundaries, and, each of the grains:
includes one or more of a transition metal or post-transition metal oxide or fluoride,
includes one or more lanthanide row atoms having a concentration in a range from about 0.1 to 10 mol %;
has a thickness in a range from about 0.5 to 30 nm; and
has an amorphous, polycrystalline or composite amorphous/polycrystalline atomic structure.

14. The method of claim 13, wherein the forming by ALD includes repeatedly sequentially exposing the outer surface of the core cathode body to gaseous deposition precursors of the transition metal or the post-transition metal, the oxide or the fluoride and the lanthanide row atoms.

15. The method of claim 14,
wherein:
the forming by ALD includes repeatedly sequentially exposing the outer surface of the core cathode body to gaseous deposition precursors of the transition metal or the post-transition metal, the oxide or the fluoride and the lanthanide row atoms, and:
the transition metal or post-transition metal oxide of the surface cathode coating layer is one or more of TiO₂, ZnO, ZrO₂, HfO₂ or Al₂O₃ and the precursor gases of Ti, Zn, Zr, Hf and Al are TiCl₄, Diethylzinc, TEMA-Zr, TEMA-Hf and Trimethylaluminum, respectively, and the precursor gas for O are O₂, H₂O, O₃ or mixtures thereof, or,
the transition metal or post-transition metal fluoride of the surface cathode coating layer is one or more of FeF₂, CuF₂, or AlF₃ and the precursor gases of Fe(CO)₅, Cu(OCHMeCH₂NMe₂)₂, and Trimethylaluminum, respectively, and the precursor gas for the fluoride is HF.

16. The method of claim 14, wherein the lanthanide row atoms of the surface cathode coating layer is one or more of La, Ce, Sm or Gd and the precursor gases are La(C₅H₅)₃, Ce(iPrCp)₂(N-iPr-amd), C₂₇H₃₉Sm and C₂₇H₃₉Gd respectively.

17. The method of claim 14, wherein the repeated sequential exposing of the ALD is performed at a temperature value in a range from 100 to 800° C. at cycling rates from 0.2 to 0.3 nm atomic layer per for 2 to 50 cycles to provide the thickness.

18. The method of claim 13, further including, after forming the core cathode body and the surface cathode coating layer, applying a post-ALD thermal anneal, the anneal including a temperature value in a range from 200 to 800° C. for a time interval in a range from 1 to 24 hours.

19. The method of claim 13, wherein the at least partially surrounding surface cathode coating layer contacts about 80 percent or more of the outer surface of the core cathode body.

20. The method of claim 13,
further including assembling the cathode composition as a plurality of layers in a cathode electrode structure where the layers are separated from each other by an electrolyte medium including lithium ions.

21. The composition of claim 1, wherein the surface cathode coating layer has the composite amorphous/polycrystalline atomic structure with greater than 20 to less than 80% crystalline and balance amorphous atomic structures.

22. The composition of claim 1, wherein the surface cathode coating layer has the polycrystalline atomic structure with 80% or greater crystalline structures.
